(19) United States
(12) Patent Application Publication
(10) Pub. No.: US 2024/0414976 A1
(43) Pub. Date: Dec. 12, 2024

(54) DISPLAY PANEL INCLUDING LIGHT EMITTING ELEMENT AND METHOD FOR MANUFACTURING LIGHT EMITTING ELEMENT

(71) Applicant: Samsung Display Co., LTD., Yongin-si (KR)

(72) Inventors: JIYOON KIM, Yongin-si (KR); YOOLGUK KIM, Yongin-si (KR); HYEONSIK KIM, Yongin-si (KR); SANGHO LEE, Yongin-si (KR); HEEWOON IM, Yongin-si (KR)

(21) Appl. No.: 18/433,169

(22) Filed: Feb. 5, 2024

(30) Foreign Application Priority Data
Jun. 12, 2023 (KR) 10-2023-0075126

(51) Int. Cl. H10K 59/80; H10K 50/115; H10K 59/12

(52) U.S. Cl. CPC H10K 59/80517; H10K 50/115; H10K 59/1201

(57) ABSTRACT

A display panel includes a base layer, a circuit layer disposed on the base layer, and a light emitting element disposed on the circuit layer. The light emitting element includes a barrier layer including a metal and a metal oxide, a hydrogen supply layer disposed on the barrier layer, and including an inorganic material, a first electrode disposed on the hydrogen supply layer, a light emitting layer disposed on the first electrode, and including a quantum dot, and a second electrode disposed on the light emitting layer.

This application claims priority to Korean Patent Application No. 10-2023-0075126, filed on Jun. 12, 2023, and all the benefits accruing therefrom under 35 U.S.C. § 119, the content of which in its entirety herein incorporated by reference.

### BACKGROUND

### 1. Field

The disclosure herein relates to a display panel including a light emitting element and a method for manufacturing the light emitting element.

### 2. Description of the Related Art

Various display devices used for multimedia devices such as a television, a mobile phone, a tablet computer, a navigation system, and a game machine are being developed. Such a display device may include a self-luminescence display element which may realize display by allowing a light emitting material including an organic or inorganic compound to emit light.

Recently, a light emitting element using a quantum dot as a light emitting material is suggested to improve the color reproducibility of a display device.

### SUMMARY

In a display device including a light emitting element using a quantum dot as a light emitting material, an improvement in luminous efficiency and lifespan of the light emitting element using the quantum dots is desired.

Embodiments of the disclosure provide a light emitting element with improved luminous efficiency and lifespan, and with improved process reliability.

Embodiments of the disclosure also provide a display panel with reduced display defects by effectively preventing variation in properties of a transistor electrically connected to a light emitting element.

An embodiment of the invention provides a display panel including a base layer, a circuit layer disposed on the base layer, and a light emitting element disposed on the circuit layer, where the light emitting element includes a barrier layer including a metal and a metal oxide, a hydrogen supply layer disposed on the barrier layer, and including an inorganic material, a first electrode disposed on the hydrogen supply layer, a light emitting layer disposed on the first electrode, and including a quantum dot, and a second electrode disposed on the light emitting layer.

In an embodiment, the hydrogen supply layer may include hydrogen impurities, where the hydrogen impurities are diffused into the light emitting layer.

In an embodiment, the hydrogen supply layer may include at least one selected from silicon nitride, silicon oxide, and silicon oxynitride.

In an embodiment, the thickness of the hydrogen supply layer may be about 2000 angstroms or less.

In an embodiment, the barrier layer may include a first layer including a metal, and a second layer disposed on the first layer, and including a metal oxide.

In an embodiment, a resonance distance of the light emitting element may be defined as a distance between an upper surface of the first layer and a lower surface of the second electrode.

In an embodiment, the thickness of the first layer may be about 500 angstroms or less, and the thickness of the second layer is in a range of about 50 angstroms to about 100 angstroms.

In an embodiment, the content of the metal oxide in the barrier layer may gradually increase in a direction toward the light emitting layer.

In an embodiment, the metal oxide may include aluminum oxide.

In an embodiment, the metal may include at least one selected from aluminum and silver.

In an embodiment, the circuit layer may include at least one transistor electrically connected to the light emitting element, a connection electrode electrically connected to the transistor, and an insulation layer disposed between the connection electrode and the barrier layer, where the transistor includes an oxide semiconductor.

In an embodiment, the first electrode may cover the hydrogen supply layer and the barrier layer, and may be connected to the connection electrode via a contact-hole defined through the insulation layer.

In an embodiment, the barrier layer may be connected to the connection electrode via a contact-hole defined through the insulation layer, and the first electrode may cover the hydrogen supply layer, and may be in contact with an upper surface of the barrier layer exposed from the hydrogen supply layer.

In an embodiment, the display panel may further include an additional barrier layer disposed between the insulation layer and the barrier layer and in contact with each of the insulation layer and the barrier layer, where the additional barrier layer includes a transparent conductive oxide.

In an embodiment, the first electrode may include a transparent conductive oxide.

In an embodiment, the thickness of the first electrode may be in a range of about 500 angstroms to about 1000 angstroms.

In an embodiment, the light emitting element may be provided in plural, and a plurality of light emitting elements may include a first light emitting element and a second light emitting element, which emit light of different colors, respectively, where the barrier layer of the first light emitting element and the barrier layer of the second light emitting element are spaced apart from each other, and the hydrogen supply layer of the first light emitting element and the hydrogen supply layer of the second light emitting element are spaced apart from each other.

In an embodiment, the light emitting layer of the first light emitting element may include a first quantum dot, the light emitting layer of the second light emitting element may include a second quantum dot, and a diameter of the first quantum dot and a diameter of the second quantum dot may be different from each other.

In an embodiment, the light emitting element may further include a hole transport region disposed between the first electrode the light emitting layer, and an electron transport region disposed between the light emitting layer and the second electrode.

In an embodiment, the hydrogen supply layer may include hydrogen impurities, where the hydrogen impurities are diffused into the electron transport region.

In an embodiment, the light emitting element may be provided in plural, and a plurality of light emitting elements may include a first light emitting element and a second light emitting element, which emit light of different colors, respectively where a thickness of the hole transport region of the first light emitting element and a thickness of the hole transport region of the second light emitting element are different from each other.

In an embodiment, the hole transport region of each of the first light emitting element and the second light emitting element may include a hole injection layer and a hole transport layer which are sequentially stacked one on another, and a thickness of the hole injection layer of the first light emitting element and a thickness of the hole injection layer of the second light emitting element may be different from each other.

In an embodiment, the light emitting element may further include an electron transport region disposed between the first electrode the light emitting layer, and a hole transport region disposed between the light emitting layer and the second electrode.

In an embodiment, the light emitting element may be provided in plural, and a plurality of light emitting elements may include a first light emitting element and a second light emitting element, which emit light of different colors, respectively, where a thickness of the electron transport region of the first light emitting element and a thickness of the electron transport region of the second light emitting element are different from each other.

In an embodiment of the invention, a method for manufacturing a light emitting element includes forming a barrier layer including a metal and a metal oxide, forming a hydrogen supply layer disposed on the barrier layer and including an inorganic material, forming a first electrode on the hydrogen supply layer, forming a light emitting layer including a quantum dot on the first electrode, and forming a second electrode on the light emitting layer.

In an embodiment, the forming the hydrogen supply layer may include depositing the inorganic material, and the depositing the inorganic material is performed by a chemical vapor deposition method by injecting a gas including hydrogen.

In an embodiment, the forming of the barrier layer may include forming a preliminary barrier layer including a first preliminary layer including the metal and a second preliminary layer disposed on the first preliminary layer and including the metal oxide, and increasing a thickness of the second preliminary layer, where the increasing the thickness of the second preliminary layer is performed by a heat treatment process or a plasma treatment process.

In an embodiment, the method for manufacturing a light emitting element may further include, after the forming the first electrode and before the forming the light emitting layer, forming a functional layer on the first electrode, where the forming the functional layer is performed by an inkjet printing process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device according to an embodiment of the invention;

FIG. 2 is an exploded perspective view of a display device according to an embodiment of the invention;

FIG. 3 is a cross-sectional view of a display module according to an embodiment of the invention taken along line I-I′ of FIG. 1;

FIG. 4 is a plan view of an enlarged portion of a display region of a display module according to an embodiment of the invention;

FIG. 5 is a cross-sectional view of a display module according to an embodiment of the invention taken along line II-II′ of FIG. 4;

FIG. 6 is an enlarged cross-sectional view of a display panel according to an embodiment of the invention;

FIG. 7A and FIG. 7B are enlarged cross-sectional views of a light emitting element according to an embodiment of the invention;

FIG. 8 is an enlarged cross-sectional view of a display panel according to an embodiment of the invention;

FIG. 9 is an enlarged cross-sectional view of a display panel according to an embodiment of the invention;

FIG. 10 is a cross-sectional view of a display module according to an embodiment of the invention taken along line II-II′ of FIG. 4;

FIG. 11A and FIG. 11B are enlarged cross-sectional views of a light emitting element according to an embodiment of the invention; and

FIG. 12A to FIG. 12H are cross-sectional views schematically showing processes of a method for manufacturing a light emitting element according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the invention.

In addition, terms such as “below,” “lower,” “above,” “upper,” and the like are used to describe the relationship of the components shown in the drawings. The terms are used as a relative concept and are described with reference to the direction indicated in the drawings.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

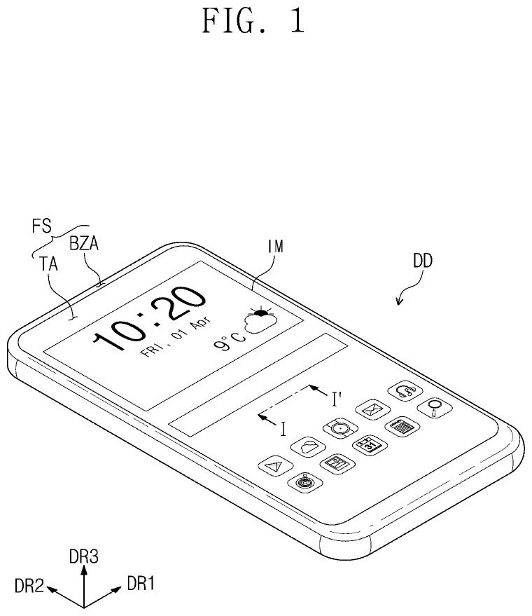

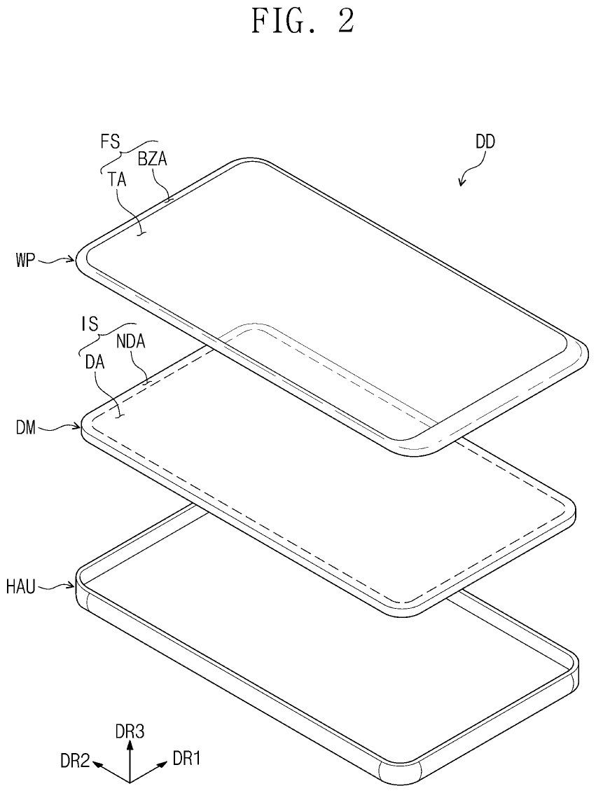

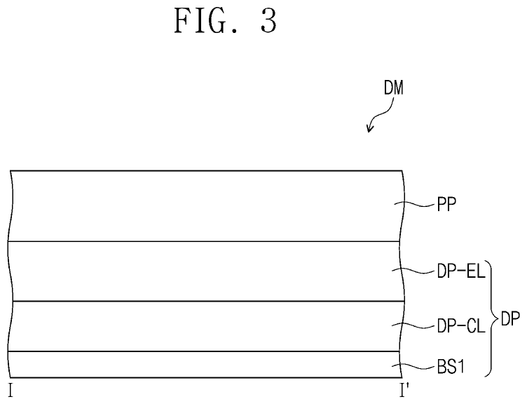

FIG. 1 is a perspective view of a display device according to an embodiment of the invention. FIG. 2 is an exploded perspective view of a display device according to an embodiment of the invention. FIG. 3 is a cross-sectional view of a display module according to an embodiment of the invention taken along line I-I′ of FIG. 1.

In an embodiment, a display device DD may be a large electronic device such as a television, a monitor, or an external advertisement board. In addition, the display device DD may be a small-and-medium-sized electronic device such as a personal computer, a laptop computer, a personal digital terminal, a car navigation system unit, a game console, a smart phone, a tablet, or a camera. In addition, it should be understood that these are merely examples, and may be employed as other display devices without departing from the invention. In an embodiment, as shown in FIG. 1, the display device DD may be a smart phone, for example.

Referring to FIG. 1 to FIG. 3, an embodiment of the display device DD may display an image IM toward a third direction DR3 on a display surface FS parallel to each of a first direction DR1 and a second direction DR2. The image IM may include both a moving image and a still image. In an embodiment, as shown in FIG. 1, the image IM may include a watch window and icons, for example. The display surface FS on which the image IM is displayed may correspond to the front surface of display device DD.

In an embodiment, a front surface (or an upper surface) and a rear surface (or a lower surface) of each member are defined on the basis of a direction in which the image IM is displayed. The front surface and the rear surface oppose each other in the third direction DR3 and a normal direction of each of the front surface and the rear surface may be parallel to the third direction DR3. In the disclosure, directions indicated by the first to third directions DR1, DR2, and DR3 are a relative concept, and may be converted to different directions. In the disclosure, “on a plane” may mean when viewed in the third direction DR3.

As illustrated in FIG. 2, the display device DD according to an embodiment may include a window WP, a display module DM, and a housing HAU. The window WP and the housing HAU may be coupled to each other to configure the appearance of the display device DD.

The window WP may include an optically transparent insulation material. In an embodiment, for example, the window WP may include glass or plastic. The front surface of the window WP may define the display surface FS of the display device DD. In an embodiment, as shown in FIGS. 1 and 2, the display surface FS may include a transmissive region TA and a bezel region BZA. The transmissive region TA may be an optically transparent region. In an embodiment, for example, the transmissive region TA may be a region having a visible light transmittance of about 90% or higher.

The bezel region BZA may be a region having a relatively low light transmittance compared to the transmissive region TA. The bezel region BZA may define the shape of the transmissive region TA. The bezel region BZA is adjacent to the transmissive region TA, and may surround the transmissive region TA. However, this is only an example, and in the window WP according to an embodiment of the invention, the bezel region BZA may be omitted. The window WP may further include at least one functional layer among a fingerprint prevention layer, a hard coating layer, and a reflection prevention layer, and is not limited to any one embodiment.

The display module DM may be disposed in a lower portion of the window WP. The display module DM may be a component which substantially generates the image IM. The image IM generated in the display module DM is displayed on the display surface IS of the display module DM, and is visually recognized by a user from the outside through the transmissive region TA.

The display module DM includes a display region DA and a non-display region NDA. The display region DA may be a region activated by an electrical signal. The non-display region NDA is adjacent to the display region DA. The non-display region NDA may surround the display region DA. The non-display region NDA is a region covered by the bezel region BZA, and may not be visually recognized from the outside.

In an embodiment, as illustrated in FIG. 3, the display module DM may include a display panel DP and an optical member PP.

In the display module DM according to an embodiment, the display panel DP may be a light emitting-type display panel. The display panel DP may be a quantum-dot light emitting display panel including a quantum-dot light emitting element.

In an embodiment, the display panel DP may include a first base layer BS1, a circuit layer DP-CL, and a display element layer DP-EL.

The first base layer BS1 may be a member which provides a base surface on which the circuit layer DP-CL and the display element layer DP-EL are disposed. The first base layer BS1 may be a glass substrate, a metal substrate, or a plastic substrate. However, the embodiment of the invention is not limited thereto, and the first base layer BS1 may be an inorganic layer, an organic layer, or a composite material layer. The first base layer BS1 may be a flexible substrate which may be easily bent or folded.

The circuit layer DP-CL is disposed on the first base layer BS1, and the circuit layer DP-CL may include at least one insulation layer and a circuit element. The circuit element may include a signal line, a driving circuit of a pixel, or the like. The circuit layer DP-CL may be formed through a forming process of an insulation layer, a semiconductor layer, and a conductive layer by coating, deposition, and the like, and a patterning process of the insulation layer, the semiconductor layer, and the conductive layer by a photolithography process. The driving circuit of a pixel may include a plurality of transistors (not shown). In an embodiment, for example, the driving circuit of a pixel may include a switching transistor and a driving transistor for driving a light emitting element.

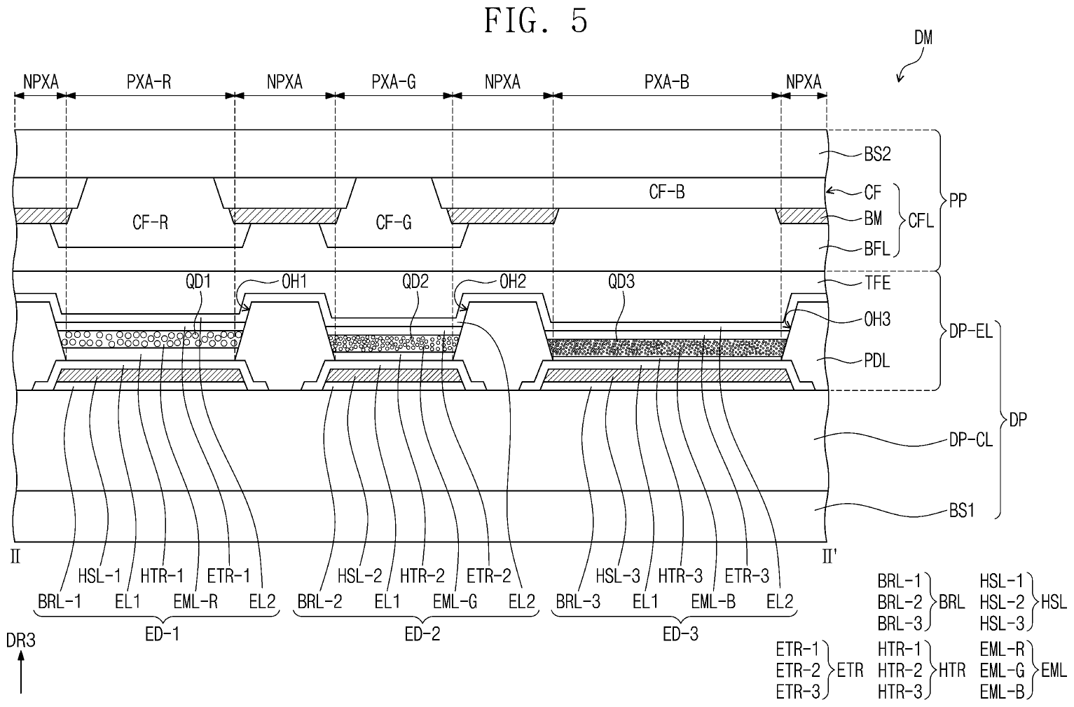

The display element layer DP-EL is disposed on the circuit layer DP-CL, and the display element layer DP-EL may include a plurality of light emitting elements ED-1, ED-2, and ED-3 (see FIG. 5). The display element layer DP-EL will be described in detail later.

The optical member PP may be disposed on the display panel DP to control reflective light in the display panel DP caused by external light. In an embodiment, for example, the optical member PP may include a color filter layer or a polarizing layer. However, according to another embodiment of the invention, the optical member PP may be omitted.

The housing HAU may be coupled to the window WP. The housing HAU may be coupled to the window WP and provide a predetermined internal space. The display module DM may be accommodated in the internal space.

The housing HAU may include a material having relatively high rigidity. In an embodiment, for example, the housing HAU may include glass, plastic, or a metal, or may include a plurality of frames and/or plates including or formed of at least one selected from the above-listed materials. The housing HAU may effectively protect components of the display device DD accommodated in the internal space from an external impact.

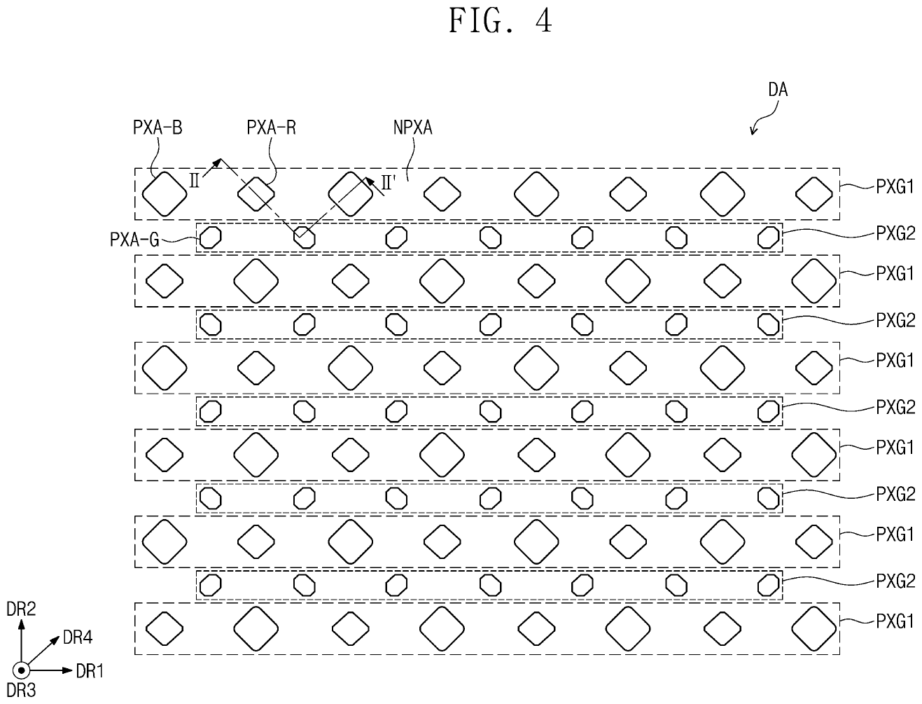

FIG. 4 is a plan view of an enlarged portion of a display region of a display module according to an embodiment of the invention. FIG. 4 illustrates a plane of the display module DM (see FIG. 2) viewed on the display surface IS (see FIG. 2) of the display module DM (see FIG. 2), which illustrates an enlarged portion of the display region DA of the display module DM (see FIG. 2).

Referring to FIG. 4, in an embodiment, the display region DA may include pixel regions PXA-R, PXA-G, and PXA-B and a peripheral region NPXA surrounding the pixel regions PXA-R, PXA-G, and PXA-B.

The pixel regions PXA-R, PXA-G, and PXA-B may correspond to regions from which light provided from light emitting elements ED-1, ED-2, and ED-3 to be described later with reference to FIG. 5 is emitted. The pixel regions PXA-R, PXA-G, and PXA-B may include first to third pixel regions PXA-R, PXA-G, and PXA-B. The first to third pixel regions PXA-R, PXA-G, and PXA-B may be distinguished according to the color of light emitted toward the outside of the display module DM (see FIG. 2).

The first to third pixel regions PXA-B, PXA-G, and PXA-R may respectively provide first to third color lights which have different colors from each other. In an embodiment, for example, the first color light may be red light, the second color light may be green light, and the third color light may be blue light. However, the first to third color lights are not limited to the above examples.

The peripheral region NPXA sets or defines boundaries of the first to third pixel regions PXA-R, PXA-G, and PXA-B, and may effectively prevent color mixing between the first to third pixel regions PXA-R, PXA-G, and PXA-B.

Each of the first to third pixel regions PXA-R, PXA-G, and PXA-B is provided in plural to be repeatedly disposed while having a predetermined arrangement form in the display region DA. In an embodiment, for example, the first and third pixel regions PXA-R and PXA-B may be alternately arranged along the first direction DR1 and form a first group PXG1. The second pixel regions PXA-G may be arranged along the first direction DR1 and form a second group PXG2. Each of the first group PXG1 and the second group PXG2 may be provided in plural, and the first groups PXG1 and the second groups PXG2 may be alternately arranged along the second direction DR2.

One second pixel region PXA-G may be disposed spaced apart in a fourth direction DR4 from one first pixel region PXA-R or one third pixel region PXA-B. The fourth direction DR4 may be defined as a direction between the first and second directions DR1 and DR2.

FIG. 4 illustrates an arrangement form of the first to third pixel regions PXA-R, PXA-G, and PXA-B in an embodiment, but the first to third light emitting regions PXA-R, PXA-G, and PXA-B may be arranged in various forms without being limited thereto. In an embodiment, the first to third pixel regions PXA-R, PXA-G, and PXA-B may have a PENTILE™ arrangement form as illustrated in FIG. 4. Alternatively, the first to third pixel regions PXA-R, PXA-G, and PXA-B may have a Stripe arrangement form, or a Diamond Pixel™ arrangement form.

The first to third pixel regions PXA-R, PXA-G, and PXA-B may have various shapes on a plane. In an embodiment, for example, the first to third pixel regions PXA-R, PXA-G, and PXA-B may have shapes such as polygons, circles, ovals, or the like. FIG. 4 illustrates an embodiment where each of the first and third pixel regions PXA-R and PXA-B has a quadrangular shape (or a rhombic shape) on a plane, and the second pixel region PXA-G has an octagonal shape.

The first to third pixel regions PXA-R, PXA-G, and PXA-B may have a same shape as each other on a plane, or at least some thereof may have different shapes from each other. FIG. 4 illustrates the first and an embodiment where third pixel regions PXA-R and PXA-B have a same shape as each other on a plane and the second pixel region PXA-G has a shape different from the shape of the first and third pixel regions PXA-R and PXA-B.

At least some of the first to third pixel regions PXA-R, PXA-G, and PXA-B may have different sizes or areas (e.g. a planar area) from each other on a plane. According to an embodiment, the planar area of the first pixel region PXA-R that emits red light may be larger than the planar area of the second pixel region PXA-G that emits green light, and smaller than the planar area of the third pixel region PXA-B that emits blue light. However, the relationship between large and small sizes or areas of the first to third pixel regions PXA-R, PXA-G, and PXA-B according to the color of emitted light is not limited thereto, and may vary depending on the design of the display module DM (see FIG. 2). In addition, the embodiment of the invention is not limited thereto, and the first to third pixel regions PXA-R, PXA-G, and PXA-B may have a same size or area as each other on a plane.

In embodiments of the invention, the shapes, areas, arrangements, or the like of the first to third pixel regions PXA-R, PXA-G, and PXA-B of the display module DM (see FIG. 2) may be designed in various ways in accordance with the color of emitted light, or the shape and configuration of the display module DM (see FIG. 2), and are not limited to those of the embodiment illustrated in FIG. 4.

FIG. 5 is a cross-sectional view of a display module according to an embodiment of the invention taken along line II-II′ of FIG. 4.

Referring to FIG. 5, the display module DM according to an embodiment may include the display panel DP and the optical member PP disposed on the display panel DP, and the display panel DP may include the first base layer BS1, the circuit layer DP-CL, and the display element layer DP-EL.

In an embodiment, the display device layer DP-EL may include light emitting elements ED-1, ED-2, and ED-3, a pixel definition layer PDL, and an encapsulation layer TFE.

The light emitting elements ED-1, ED-2, and ED-3 may include a first light emitting element ED-1, a second light emitting element ED-2, and a third light emitting element ED-3. Each of the first to third light emitting elements ED-1, ED-2, and ED-3 may include a barrier layer BRL, a hydrogen supply layer HSL, a first electrode EL1, a hole transport region HTR, a light emitting layer EML, an electron transport region ETR, and a second electrode EL2 which are sequentially stacked one on another.

The barrier layer BRL may be disposed on the circuit layer DP-CL. The barrier layer BRL may include first to third barrier layers BRL-1, BRL-2, and BRL-3. The first to third barrier layers BRL-1, BRL-2, and BRL-3 may respectively correspond to the first to third pixel regions PXA-B, PXA-G, and PXA-R and be disposed as patterns spaced apart from each other.

The hydrogen supply layer HSL may be disposed on the barrier layer BRL. The hydrogen supply layer HSL may include first to third hydrogen supply layers HSL-1, HSL-2, and HSL-3. The first to third hydrogen supply layers HSL-1, HSL-2, and HSL-3 may respectively correspond to the first to third pixel regions PXA-R, PXA-G, and PXA-B and be disposed as or defined by patterns spaced apart from each other. The first hydrogen supply layer HSL-1 may be disposed on the first barrier layer BRL-1, the second hydrogen supply layer HSL-2 may be disposed on the second barrier layer BRL-2, and the third hydrogen supply layer HSL-3 may be disposed on the third barrier layer BRL-3.

The first electrode EL1 may be disposed on the circuit layer DP-CL. In an embodiment, the first electrode EL1 may be disposed on the hydrogen supply layer HSL. The first electrode EL1 is provided in plural, and the first electrodes EL1 may respectively correspond to the first to third pixel regions PXA-R, PXA-G, and PXA-B and be disposed in each of the light emitting elements ED-1, ED-2, and ED-3 as patterns spaced apart from each other. In an embodiment, each of the first electrodes EL1 may be an anode.

The first electrode EL1 of the first light emitting element ED-1 may be disposed on the first hydrogen supply layer HSL-1. The first electrode EL1 of the first light emitting element ED-1 may cover the first hydrogen supply layer HSL-1. The first electrode EL1 of the second light emitting element ED-2 may be disposed on the second hydrogen supply layer HSL-2. The first electrode EL1 of the second light emitting element ED-2 may cover the second hydrogen supply layer HSL-2. The first electrode EL1 of the third light emitting element ED-3 may be disposed on the third hydrogen supply layer HSL-3. The first electrode EL1 of the third light emitting element ED-3 may cover the third hydrogen supply layer HSL-3.

The pixel definition layer PDL may be disposed on the circuit layer DP-CL. In an embodiment, pixel openings OH1, OH2, and OH3 may be defined in the pixel definition layer PDL. Each of the pixel openings OH1, OH2, and OH3 may expose at least a portion of a corresponding first electrode among the first electrodes EL1. The pixel openings OH1, OH2, and OH3 may include a first pixel opening OH1, a second pixel opening OH2, and a third pixel opening OH3.

Each of the pixel regions PXA-R, PXA-G, and PXA-B may be a region distinguished or separated by the pixel definition layer PDL. The peripheral region NPXA is a region between adjacent pixel regions PXA-R, PXA-G, and PXA-B and may be a region corresponding to the pixel definition layer PDL. In the specification, each of the pixel regions PXA-R, PXA-G, and PXA-B may correspond to a pixel or a pixel area. The pixel definition layer PDL may distinguish the light emitting elements ED-1, ED-2, and ED-3.

In the first electrodes EL1, a region exposed via the first pixel opening OH1 by not being covered by the pixel definition layer PDL is defined as the first pixel region PXA-R. Each of the first barrier layer BRL-1 and the first hydrogen supply layer HSL-1 may overlap the first pixel opening OH1, that is, the first pixel region PXA-R. In the first electrodes EL1, a region exposed via the second pixel opening OH2 by not being covered by the pixel definition layer PDL is defined as the second pixel region PXA-G. Each of the second barrier layer BRL-2 and the second hydrogen supply layer HSL-2 may overlap the second pixel opening OH2, that is, the second pixel region PXA-G. In the first electrodes EL1, a region exposed via the third pixel opening OH3 by not being covered by the pixel definition layer PDL is defined as the third pixel region PXA-B. Each of the third barrier layer BRL-3 and the third hydrogen supply layer HSL-3 may overlap the third pixel opening OH3, that is, the third pixel region PXA-B.

In an embodiment, the hole transport region HTR may be disposed on the first electrodes EL1. The hole transport region HTR may include a first hole transport region HTR-1 disposed in the first pixel opening OH1, a second hole transport region HTR-2 disposed in the second pixel opening OH2, and a third hole transport region HTR-3 disposed in the third pixel opening OH3. In an embodiment, the first to third hole transport regions HTR-1, HTR-2, and HTR-3 may be respectively disposed in the first to third pixel openings OH1, OH2, and OH3 and be disposed as or defined by patterns spaced apart from each other.

In an embodiment, the first to third hole transport regions HTR-1, HTR-2, and HTR-3 may have different thicknesses from each other. This will be described later in detail.

The light emitting layer EML may be disposed on the hole transport region HTR. The light emitting layer EML may include a first light emitting layer EML-R disposed on the first hole transport region HTR-1 in the first pixel opening OH1, a second light emitting layer EML-G disposed on the second hole transport region HTR-2 in the second pixel opening OH2, and a third light emitting layer EML-B disposed on the third hole transport region HTR-3 in the third pixel opening OH3. In an embodiment, the first to third light emitting layers EML-R, EML-G, and EML-B may be respectively disposed in the first to third pixel openings OH1, OH2, and OH3 and be disposed as or defined by patterns spaced apart from each other.

The first to third light emitting layers EML-R, EML-G, and EML-B may include quantum dots QD1, QD2, and QD3. The quantum dots QD1, QD2, and QD3 may include a first quantum dot QD1, a second quantum dot QD2, and a third quantum dot QD3.

The first light emitting layer EML-R may include the first quantum dot QD1. The first quantum dot QD1 may emit red light which is the first color light. The second light emitting layer EML-G may include the second quantum dot QD2. The second quantum dot QD2 may emit green light which is the second color light. The third light emitting layer EML-B may include the third quantum dot QD3. The third quantum dot QD3 may emit blue light which is the third color light.

In an embodiment, the first color light may be light having a center (or peak) wavelength in a wavelength region of about 410 nanometers (nm) to about 480 nm, the second color light may be light having a center wavelength in a wavelength region of about 500 nm to about 570 nm, and the third color light may be light having a center wavelength in a wavelength region of about 625 nm to about 675 nm.

In the specification, a quantum dot refers to a crystal of a semiconductor compound. A quantum dot may emit light of various light emission wavelengths depending on a size of the crystal. A quantum dot may emit light of various light emission wavelengths by controlling an element ratio in the quantum dot compound.

The diameter of the quantum dot may be, for example, in a range of about 1 nm to about 10 nm.

The quantum dot may be synthesized by a wet chemical process, an organometallic chemical deposition process, a molecular beam epitaxy process, or a similar process.

The wet chemical process is a method of mixing an organic solvent and a precursor material, and then growing a quantum dot particle crystal. When the crystal is growing, the organic solvent naturally serves as a dispersant coordinated on the surface of the quantum dot crystal, and may control the growth of the crystal. Therefore, the wet chemical process is easier than a vapor deposition method such as metal organic chemical vapor deposition (MOCVD) or molecular beam epitaxy (MBE), and may control the growth of quantum dot particles through a low-cost process.

A core of a quantum dot may be selected from a Group II-VI compound, a Group III-V compound, a Group III-VI compound, a Group I-III-VI compound, a Group IV-VI compound, a Group IV element, a Group IV compound, and a combination thereof.

The Group II-VI compound may be selected from a binary compound selected from CdSe, CdTe, CdS, ZnS, ZnSe, ZnTe, ZnO, HgS, HgSe, HgTe, MgSe, MgS, and a mixture thereof, a ternary compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. Here, the Group II-VI semiconductor compound may further include a Group I metal and/or a Group IV element. The Group I-TI-VI compound may be selected from CuSnS or CuZnS, and the Group II-IV-VI compound may be selected from ZnSnS and the like. The Group I-II-IV-VI compound may be selected from a quaternary compound selected from Cu₂ZnSnS₂, Cu₂ZnSnS₄, Cu₂ZnSnSe₄, Ag₂ZnSnS₂, and a mixture thereof.

An example of the Group III-V semiconductor compound may include a binary compound such as GaN, GaP, GaAs, GaSb, AlN, AlP, AlAs, AlSb, InN, InP, InAs, InSb, etc., a ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, etc., a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, etc., or any combination thereof. Here, the Group III-V semiconductor compound may further include a Group II element. An example of the Group III-V semiconductor compound further including a Group II element may include InZnP, InGaZnP, InAlZnP, etc.

An example of the Group III-VI semiconductor compound may include a binary compound such as GaS, Ga₂S₃, GaSe, Ga₂Se₃, GaTe, InS, InSe, In₂Se₃, InTe, etc., a ternary compound such as InGaS₃, InGaSe₃, etc., or any combination thereof.

An example of the Group I-III-VI semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, etc., a quaternary compound such as AgInGaS₂, AgInGaSe₂, etc., or any combination thereof.

An example of the Group IV-VI semiconductor compound may include a binary compound such as SnS, SnSe, SnTe, PbS, PbSe, PbTe, etc., a ternary compound such as SnSeS, SnSeTe, SnSTe, PbSeS, PbSeTe, PbSTe, SnPbS, SnPbSe, SnPbTe, etc., a quaternary compound such as SnPbSSe, SnPbSeTe, SnPbSTe, etc., or any combination thereof.

An example of the Group II-IV-V compound may be a ternary compound selected from ZnSnP, ZnSnP₂, ZnSnAs₂, ZnGeP₂, ZnGeAs₂, CdSnP₂, and CdGeP₂, and a mixture thereof.

The group IV element or compound may include a single-element compound such as Si, Ge, etc., a binary element compound such as SiC, SiGe, etc., or any combination thereof.

Each element included in a multi-element compound such as the binary compound, the ternary compound, and the quaternary compound, may be in a particle at a uniform concentration or non-uniform concentration. That is, the above formula means types of elements included in a compound, and element ratios in the compound may be different. For example, AgInGaS₂ may mean AgInₓGa₁₋ₓS₂ (x is a real number between 0 and 1).

In an embodiment, the quantum dot may have a single structure in which the concentration of each element included in the corresponding quantum dot is uniform or a dual core-shell structure. For example, a material included in the core and a material included in the shell may be different from each other.

The shell of the quantum dot may serve as a protective layer to prevent the chemical deformation of the core to maintain semiconductor properties, and/or a charging layer to impart electrophoresis properties to the quantum dot. The shell may be a single layer, or multiple layers. In the core/shell structure, the binary compound, the ternary compound, or the quaternary compound may have a concentration gradient in which the concentration of an element in the shell becomes lower toward the center.

An example of the shell of the quantum dot may be a metal or non-metal oxide, a semiconductor compound, or a combination thereof. An example of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc., a ternary compound such as MgAl₂O₄, CoFe₂O₄, NiFe₂O₄, CoMn₂O₄, etc., or any combination thereof. An example of the semiconductor compound may include, as described herein, a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, or any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Each element included in a multi-element compound such as the binary compound or the ternary compound may be in a particle at a uniform concentration or non-uniform concentration. That is, the above formula means types of elements included in a compound, and element ratios in the compound may be different.

The quantum dot may have a full width of half maximum (FWHM) of a light emission wavelength spectrum of about 45 nm or less, e.g., about 40 nm or less, or about 30 nm or less, and color purity or color reproducibility may be improved in the above range. In addition, light emitted through such a quantum dot is emitted in all directions, so that a wide viewing angle may be improved.

In addition, a quantum dot may specifically be in the form of spherical, pyramidal, multi-arm, or cubic nanoparticles, nanotubes, nanowires, nanofibers, nanoplate particles, etc.

Since it is possible to adjust an energy band gap by adjusting the size of the quantum dot or adjusting an element ratio in a quantum dot compound, it is possible to obtain light of various wavelength bands from a quantum-dot light emitting layer. Therefore, a light emitting element which emits light of various wavelengths may be implemented by using a quantum dot as described above (using quantum dots of different sizes or having different element ratios in a quantum dot compound). Specifically, the adjustment of the size of the quantum dot or the element ratio in the quantum dot compound may be selected to emit red, green, and/or blue light. In addition, the quantum dots may be configured to emit white light by combining light of various colors.

FIG. 5 illustrates an embodiment where the first to third quantum dots QD1, QD2, and QD3 have different sizes (e.g., diameter) from each other. However, the embodiment of the invention is not limited thereto, and the first to third quantum dots QD1, QD2, and QD3 may be a same size (e.g., diameter) as each other.

In an embodiment, the electron transport region ETR may be disposed on the light emitting layer EML. The electron transport region ETR may include a first electron transport region ETR-1 disposed in the first pixel opening OH1 and disposed on the first light emitting layer EML-R, a second electron transport region ETR-2 disposed in the second pixel opening OH2 and disposed on the second light emitting layer EML-G, and a third electron transport region ETR-3 disposed in the third pixel opening OH3 and disposed on the third light emitting layer EML-B.

FIG. 5 illustrates an embodiment where the electron transport region ETR is provided in the form of a plurality of patterns spaced apart from each other and the first to third electron transport regions ETR-1, ETR-2, and ETR-3 are respectively disposed in the first to third pixel openings OH1, OH2, and OH3, but the embodiment of the invention is not limited thereto, and the electron transport region ETR may be provided as a common layer, and the first to third electron transport regions ETR-1, ETR-2, and ETR-3 may be distinguished in the common layer or defined by portions of the common layer.

The second electrode EL2 may be disposed on the electron transport region ETR. The second electrode EL2 of the first to third light emitting elements ED-1, ED-2, and ED-3 may be connected to each other and provided in a single shape or integrally formed with each other as a single unitary and indivisible part. That is, the second electrode EL2 may be provided in the form of a common layer. In an embodiment, the second electrode EL2 may be a cathode.

The encapsulation layer TFE may cover the light emitting elements ED-1, ED-2, and ED-3, thereby encapsulating the light emitting elements ED-1, ED-2, and ED-3. The encapsulation layer TFE is disposed on the second electrode EL2, and may be disposed to fill the pixel openings OH1, OH2, and OH3.

The encapsulation layer TFE may have a multi-layered structure in which an inorganic layer/organic layer are repeated. In an embodiment, for example, the encapsulation layer TFE may have a structure of an inorganic layer/an organic layer/an inorganic layer. The inorganic layer may protect the light emitting elements ED-1, ED-2, and ED-3 from external moisture, and the organic layer may effectively prevent imprint defects of the light emitting elements ED-1, ED-2, and ED-3 caused by foreign substances introduced during a manufacturing process.

In an embodiment, the optical member PP may include a second base layer BS2 and a color filter layer CFL. That is, the display module DM according to an embodiment may include the color filter layer CFL disposed on the light emitting elements ED-1, ED-2, and ED-3 of the display panel DP.

The second base layer BS2 may be a member which provides a base surface on which the color filter layer CFL or the like are disposed. The second base layer BS2 may be a glass substrate, a metal substrate, a plastic substrate, or the like. However, the embodiment of the invention is not limited thereto, and the second base layer BS2 may be an inorganic layer, an organic layer, or a composite material layer.

The color filter layer CFL may include a light blocking part BM and a color filter CF. The color filter CF may include a plurality of color filters CF-R, CF-G, and CF-B. That is, the color filter layer CFL may include a first color filter CF-R which transmits the first light, a second color filter CF-G which transmits the second light, and a third color filter CF-B transmits the third light.

Each of the color filters CF-B, CF-G, and CF-R may include a polymer photosensitive resin, and a pigment or a dye. The first color filter CF-R may include a red pigment or a red dye, the second color filter CF-G may include a green pigment or a green dye, and the third color filter CF-B may include a blue pigment or a blue dye. However, the embodiment of the invention is not limited thereto, and the third color filter CF-B may not include a pigment or a dye.

The light blocking part BM may be a black matrix. The light blocking part BM may be formed by including an organic light blocking material or an inorganic light blocking material which includes a black pigment or a black dye. The light blocking part BM may effectively prevent a light leakage phenomenon, and may separate or define boundaries between adjacent color filters CF-B, CF-G, and CF-R.

The color filter layer CFL may further include a buffer layer BFL. In an embodiment, for example, the buffer layer BFL may be a protective layer for protecting the color filters CF-R, CF-G, and CF-B. The buffer layer BFL may be an inorganic material layer including at least one inorganic material among a silicon nitride (SiNₓ), a silicon oxide (SiOₓ), and a silicon acid nitride (SiOₓN_{y}). The buffer layer BFL may be formed of or defined by a single layer or a plurality of layers.

In an embodiment, as illustrated in FIG. 5, the third color filter CF-B of the color filter layer CFL may partially overlaps the first color filter CF-R and the second color filter CF-G, and may entirely overlap the peripheral region NPXA, but the embodiment of the invention is not limited thereto. In an embodiment, for example, the first to third color filters CF-R, CF-G, and CF-B may be distinguished by the light blocking part BM and may not overlap each other. In an embodiment, each the first to third color filters CF-R, CF-G, and CF-B may be disposed to correspond to (or to overlap) the first to third pixel regions PXA-R, PXA-G, and PXA-B, respectively. According to another embodiment, the color filter layer CFL may be omitted.

FIG. 5 illustrates an embodiment of the optical member PP. According to another embodiment, the optical member PP may include a polarizing layer (not shown). The polarizing layer (not shown) may block external light provided to the display panel DP from the outside. In an embodiment, the polarizing layer (not shown) may reduce reflected light generated in the display panel DP by the external light.

The polarizing layer (not shown) may be a circular polarizer having an anti-reflection function or the polarizing layer (not shown) may include a linear polarizer and a λ/4 phase retarder. In an embodiment, the polarizing layer (not shown) may be disposed on the second base layer BS2 and exposed, or the polarizing layer (not shown) may be disposed in a lower portion of the second base layer BS2.

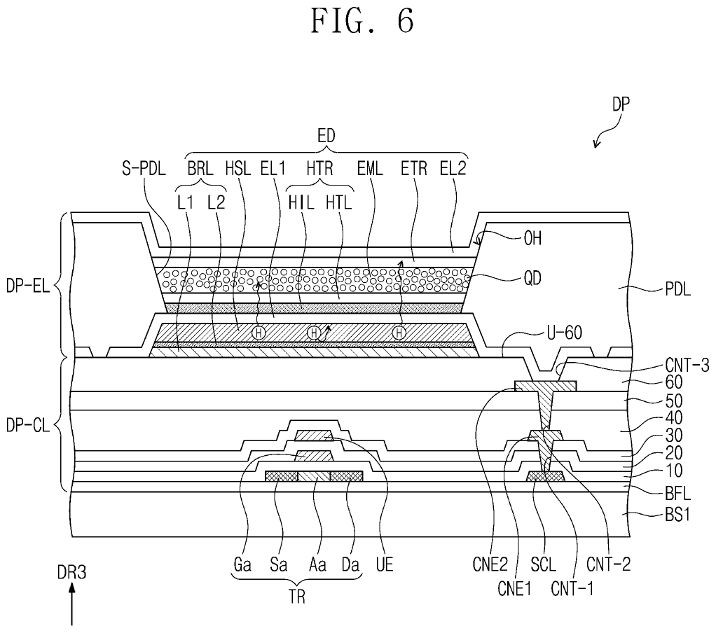

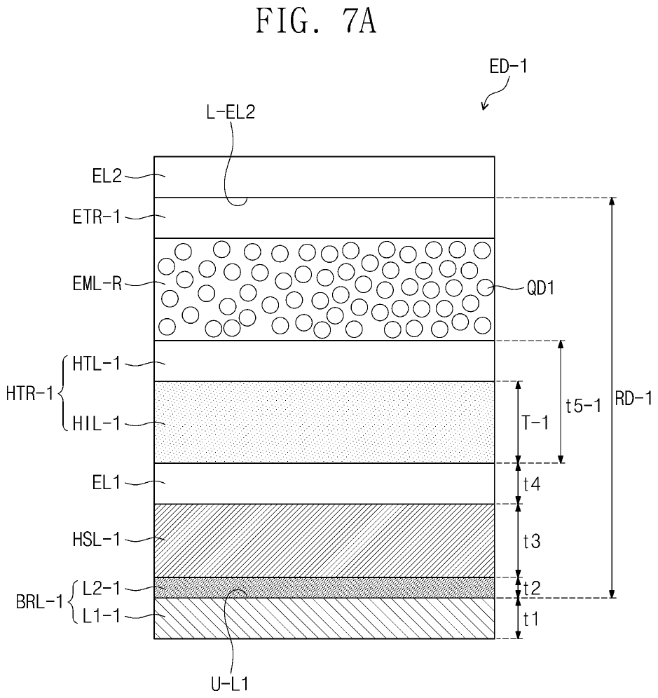

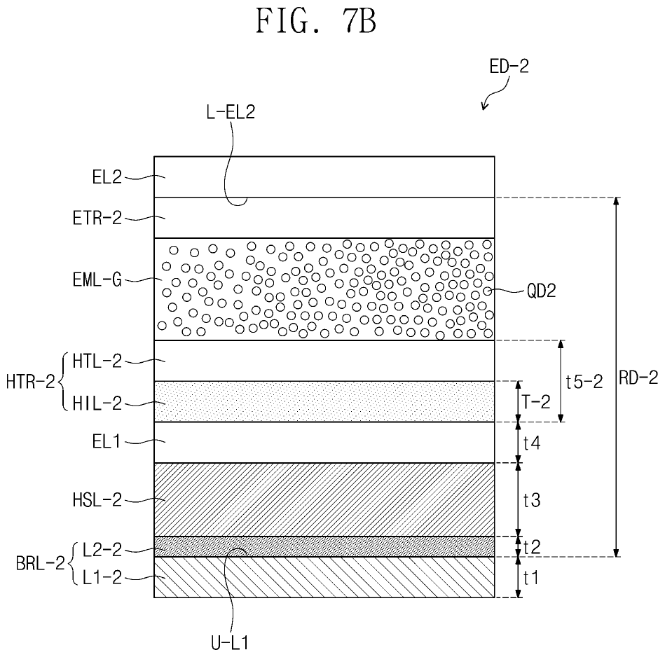

FIG. 6 is an enlarged cross-sectional view of a display panel according to an embodiment of the invention. FIG. 7A and FIG. 7B are enlarged cross-sectional views of a light emitting element according to an embodiment of the invention. FIG. 6 illustrates a region of an embodiment of display panel in which one transistor TR and one light emitting element ED are disposed in the pixels of the display panel DP. The one light emitting element ED illustrated in FIG. 6 may correspond to one of the first to third light emitting elements ED-1, ED-2, and ED-3 illustrated in FIG. 5. Among the light emitting elements ED-1, ED-2, and ED-3 illustrated in FIG. 5, FIG. 7A and FIG. 7B schematically show the first light emitting element ED-1 and the second light emitting element ED-2, respectively. The same/similar reference numerals are used for the same/similar components as those described with reference to FIG. 1 to FIG. 5, and any repetitive detailed descriptions thereof will be omitted or simplified.

Referring to FIG. 6 and FIG. 7B, in an embodiment, the circuit layer DP-CL may include a buffer layer BFL, a transistor TR, a connection signal line SCL, an upper electrode UE, connection electrodes CNE1 and CNE2, and a plurality of insulation layers 10 to 60. The plurality of insulation layers 10 to 60 may include first to sixth insulation layers 10 to 60 sequentially stacked on the buffer layer BFL. Each of the first to sixth insulation layers 10 to 60 may include an insulation layer or an organic layer.

The transistor TR may include a semiconductor pattern including a source region Sa, an active region Aa, and a drain region Da, and a gate electrode Ga. According to an embodiment, the semiconductor pattern of the transistor TR may include an oxide semiconductor. The semiconductor pattern may include a transparent conductive oxide (TCO) such as indium tin oxide (ITO), indium zinc oxide (IZO), indium gallium zinc oxide (IGZO), zinc oxide (ZnOₓ), indium oxide (In₂O₃), or the like. The zinc oxide (ZnOₓ) may be zinc oxide (ZnO) and/or zinc peroxide (ZnO₂).

The oxide semiconductor may include a plurality of regions which are distinguished one from another depending on whether a transparent conductive oxide has been reduced or not. A region in which the transparent conductive oxide has been reduced (hereinafter, a reduction region) has greater conductivity than a region in which the transparent conductive oxide has not been reduced (hereinafter, a non-reduction region). The reduction region has a larger hydrogen concentration than the non-reduction region, and substantially serves as a source/drain or a signal line of the transistor TR. The non-reduction region may substantially correspond to the active region Aa (or a channel region) of the transistor TR. That is, a partial region of the semiconductor pattern may be the active region Aa, and other partial regions may be the source region Sa and the drain region Da. The source region Sa and the drain region Da may be extended in opposite directions with the active region Aa interposed therebetween. That is, the active region Aa may be disposed between the source region Sa and the drain region Da.

The connection signal line SCL may be formed from (or defined by portions of) the semiconductor pattern, and may be disposed in (or directly on) a same layer as the source region Sa, the active region Aa, and the drain region Da of the transistor TR. According to an embodiment, the connection signal line SCL may be electrically connected to the drain region Da of the transistor TR on a plane.

The first insulation layer 10 may cover the semiconductor pattern of the circuit layer DP-CL. The gate electrode Ga may be disposed on the first insulation layer 10. The gate electrode Ga may overlap the active region Aa. The gate electrode Ga may serve as a mask in a process of doping the semiconductor pattern. The upper electrode UE may be disposed on the second insulation layer 20. The upper electrode UE may overlap the gate electrode Ga.

The first connection electrode CNE1 and the second connection electrode CNE2 may be disposed between the transistor TR and the light emitting element ED to electrically connect the transistor TR and the light emitting element ED to each other. The first connection electrode CNE1 may be disposed on the third insulation layer 30 and connected to the connection signal line SCL via a contact-hole CNT-1 defined through the first to third insulation layers 10 to 30. The second connection electrode CNE2 may be disposed on the fifth insulation layer 50 and connected to the first connection electrode CNE1 via a contact-hole CNT-2 defined through the fourth and fifth insulation layers 40 and 50.

The display element layer DP-EL may include the light emitting element ED and the pixel definition layer PDL. The light emitting element ED may include a barrier layer BRL, a hydrogen supply layer HSL, a first electrode EL1, a hole transport region HTR, a light emitting layer EML, an electron transport region ETR, and a second electrode EL2.

The barrier layer BRL may be disposed on the circuit layer DP-CL. The barrier layer BRL may be disposed on the uppermost insulation layer among the insulation layers 10 to 60 disposed in the circuit layer DP-CL, that is, the sixth insulation layer 60.

In an embodiment, the barrier layer BRL may include a first layer L1 and a second layer L2 disposed on the first layer L1.

The first layer L1 may include a metal. In an embodiment, for example, the metal included in the first layer L1 may include aluminum (Al) or silver (Ag). The first layer L1 may be referred to as a reflective electrode.

In an embodiment, a thickness t1 of the first layer L1 may be about 500 angstroms (Å) or greater. If the thickness t1 of the first layer L1 is less than about 500 angstroms (Å), it may be difficult to secure desired reflectivity, and light emission efficiency may be reduced due to insufficient resonance of light in the light emitting element ED.

The second layer L2 may include a metal oxide. In an embodiment, for example, the metal oxide included in the second layer L2 may include an aluminum oxide (Al_{X}O_{y}). Since the aluminum oxide (Al_{X}O_{y}) has a large permeation reduction factor (PRF), when the second layer L2 includes the aluminum oxide (Al_{X}O_{y}), it may be possible to reduce the diffusion of hydrogen (e.g., hydrogen impurities in a film) through the second layer L2.

In an embodiment, a thickness t2 of the second layer L2 may be about 50 angstroms (Å) to about 100 angstroms (Å). If the thickness t2 of the second layer L2 is less than about 50 angstroms (Å), the second layer L2 may have difficulty in blocking hydrogen diffusion, and if the thickness t2 of the second layer L2 is greater than about 100 angstroms (Å), it may be difficult to secure desired reflectivity due to reduced reflectivity, and light emission efficiency may be reduced due to insufficient resonance of light in the light emitting element ED.

FIG. 6 illustrates an embodiment where the barrier layer BRL is divided into the first layer L1 and the second layer L2, but the barrier layer BRL may be provided in a state in which the boundary of a layer including a metal and a layer including a metal oxide is not distinguished from each other. That is, the barrier layer BRL may be formed in the form of a single layer including both a metal and a metal oxide, and at this time, the content of the metal oxide in the barrier layer BRL may gradually increase as being upward toward the light emitting layer EML.

The hydrogen supply layer HSL may be disposed on the second layer L2 of the barrier layer BRL. In an embodiment, the hydrogen supply layer HSL may include an inorganic material. In an embodiment, for example, the inorganic material included in the hydrogen supply layer HSL may include at least one selected from a silicon nitride (SiNₓ), a silicon oxide (SiOₓ), and a silicon acid nitride (SiOₓN_{y}).

In an embodiment, the hydrogen supply layer HSL may include hydrogen. A gas injected in a process of forming the hydrogen supply layer HSL may include hydrogen, and the hydrogen in the injected gas may remain in the form of impurities in the hydrogen supply layer HSL after the process. Hereinafter, the hydrogen remaining in the hydrogen supply layer HSL is referred to as hydrogen impurities.

In an embodiment, a thickness t3 of the hydrogen supply layer HSL may be about 2000 angstroms (Å) or less. However, the embodiment of the invention is not limited thereto, and the hydrogen supply layer HSL may be provided in an appropriate thickness in consideration of an appropriate resonance distance according to the wavelength of light emitted from the light emitting layer EML and/or thicknesses of other layers in the light emitting element ED affecting the resonance distance, and the like.

The first electrode EL1 may be disposed on the sixth insulation layer 60, and may cover the barrier layer BRL and the hydrogen supply layer HSL. The first electrode EL1 may be in contact with an upper surface U-60 of the sixth insulation layer 60 exposed from the barrier layer BRL. The first electrode EL1 may be connected to the second connection electrode CNE2 via a contact-hole CNT-3 defined through the sixth insulation layer 60. That is, the first electrode EL1 may be electrically connected to the transistor TR via the second connection electrode CNE2.

In an embodiment, the first electrode EL1 may include a transparent conductive oxide (TCO). In an embodiment, for example, the first electrode EL1 may include indium tin oxide (ITO), indium zinc oxide (IZO), or the like. The first electrode EL1 may be referred to as a transparent electrode. In an embodiment, the thickness of the first electrode EL1 may be in a range of about 500 angstroms (Å) to about 1000 angstroms (Å).

The pixel definition layer PDL may include or be formed of a polymer resin. In an embodiment, for example, the pixel definition layer PDL may be formed using a polyacrylate-based resin or a polyimide-based resin. Also, the pixel definition layer PDL may be formed by further using an inorganic matter in addition to the polymer resin. In an embodiment, the pixel definition layer PDL may be formed by using a light absorbing material, or may be formed by using a black pigment or a black dye. The pixel definition layer PDL formed by using a black pigment or a black dye may implement a black pixel definition layer. When the pixel definition layer PDL is formed, carbon black and the like may be used as a black pigment or a black dye, but the embodiment of the invention is not limited thereto.

In an embodiment, the pixel definition layer PDL may include or be formed of an inorganic material. In an embodiment, for example, the pixel definition layer PDL may be formed by including a silicon nitride (SiNₓ), a silicon oxide (SiOₓ), a silicon oxynitride (SiOₓN_{y}), or the like.

In an embodiment, a side surface S-PDL of the pixel definition layer PDL may be hydrophobic. That is, the side surface S-PDL of the pixel definition layer PDL defining a pixel opening OH may be hydrophobic. In an embodiment, for example, the pixel definition layer PDL itself may be formed by including a hydrophobic material, or a hydrophobic coating layer (not shown) may be included on at least the side surface S-PDL of the pixel definition layer PDL. The side surface S-PDL of the pixel definition layer PDL may be a region in contact with the hole transport region HTR, the light emitting layer EML, and the electron transport region ETR.

The hole transport region HTR may have a single-layered structure having a single layer including or formed of a single material, a single-layered structure having a single layer including or formed of a plurality of different materials, or a multi-layered structure having a plurality of layers including or formed of a plurality of different materials. FIG. 6 to FIG. 7B illustrate an embodiment where the hole transport region HTR includes a hole injection layer HIL and a hole transport layer HTL disposed on the hole injection layer HIL.

The hole injection layer HIL may include, for example, a phthalocyanine compound such as copper phthalocyanine; N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino) triphenylamine (m-MTDATA), 4,4′4″-Tris(N,N-diphenylamino)triphenylamine (TDATA), 4,4′,4″-tris{N,-(2-naphthyl)-N-phenylamino}-triphenylamine (2-TNATA), Poly(3,4-ethylenedioxythiophene)/Poly(4-styrenesulfonate) (PEDOT/PSS), Polyaniline/Dodecylbenzenesulfonic acid (PANI/DBSA), Polyaniline/Camphor sulfonic acid PANI/CSA), (Polyaniline)/Poly(4-styrenesulfonate) (PANI/PSS), N,N′-di(naphthalene-1-yl)-N,N′-diplienyl-benzidine (NPD), triphenylamine-containing polyether ketone (TPAPEK), 4-Isopropyl-4′-methyldiphenyliodonium Tetrakis(pentafluorophenyl)borate], dipyrazino[2,3-f: 2′,3′-h] quinoxaline-2,3,6,7,10,11-hexacarbonitrile (HAT-CN), or the like.

The hole transport layer HTL may include a common material known in the art. For example, the hole transport layer HTL may further include, for example, a carbazole-based derivative such as N-phenylcarbazole and polyvinylcarbazole, a fluorene-based derivative, a triphenylamine-based derivative such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), N,N′-di(naphthalene-1-yl)-N,N′-diplienyl-benzidine (NPD), 4,4′-Cyclohexylidene bis[N,N-bis(4-methylphenyl)benzenamine](TAPC), 4,4′-Bis[N,N′-(3-tolyl)amino]-3,3′-dimethylbiphenyl (HMTPD), 1,3-Bis(N-carbazolyl)benzene (mCP), or the like.

The hole transport region HTR may further include, in addition to the hole injection layer HIL and the hole transport layer HTL, at least one selected from a hole buffer layer and an electron blocking layer. The hole buffer layer may increase light emission efficiency by compensating for a resonance distance according to the wavelength of light emitted from the light emitting layer EML. As a material included in the hole buffer layer, a material which may be included in the hole transport region HTR may be used. The electron blocking layer is a layer serving to prevent electron injection from the electron transport region ETR to the hole transport region HTR.

The electron transport region ETR may include at least one selected from a hole blocking layer, an electron transport layer, or an electron injection layer, but the embodiment of the invention is not limited thereto. FIG. 6 to FIG. 7B illustrate an embodiment where the electron transport region ETR is defined by a single layer, and the single layer may be the electron transport layer.

In an embodiment, the electron transport region ETR may include a metal oxide. The metal oxide may include an oxide of a metal including at least one selected from silicon, aluminum, zinc, indium, gallium, yttrium, germanium, scandium, titanium, tantalum, hafnium, zirconium, cerium, molybdenum, nickel, chromium, iron, niobium, tungsten, tin, or copper, and a mixture thereof, but is not limited thereto.

In an embodiment, the metal oxide may include a zinc oxide. The type of the zinc oxide is not particularly limited, but may be, for example, ZnO, ZnMgO, or a combination thereof, and Li, Y, or the like may be doped in addition to Mg. In addition, other than the zinc oxide, TiO₂, SiO₂, SnO₂, WO₃, Ta₂O₃, BaTiO₃, BaZrO₃, ZrO₂, HfO₂, Al₂O₃, Y₂O₃, ZrSiO₄, or the like may be used as an inorganic material, but the embodiment of the invention is not limited thereto.

The second electrode EL2 is disposed on the electron transport region ETR. In an embodiment, the second electrode EL2 may be a transmissive electrode, a transflective electrode, or a reflective electrode. In an embodiment, where the second electrode EL2 is a transmissive electrode, the second electrode EL2 may include or be formed of a transparent metal oxide, for example, indium tin oxide (ITO), indium zinc oxide (IZO), zinc oxide (ZnO), indium tin zinc oxide (ITZO), or the like.

In an embodiment where the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, or a compound or a mixture thereof (for example, a mixture of Ag and Mg). Alternatively, the second electrode EL2 may have a multi-layered structure including a reflective film or a transflective film, each layer therein including at least one selected from the above listed materials, and a transparent conductive film including or formed of indium tin oxide (ITO), indium zinc oxide (IZO), zinc oxide (ZnO), indium tin zinc oxide (ITZO), or the like.

Hydrogen impurities in the hydrogen supply layer HSL may be diffused into other layers disposed on an upper side or lower side of the hydrogen supply layer HSL. According to embodiments of the invention, the hydrogen impurities in the hydrogen supply layer HSL may be diffused into a portion in which the light emitting layer EML and/or the electron transport region ETR are disposed. When hydrogen is provided in the light emitting layer EML including a quantum dot QD, defects in the light emitting layer EML may be effectively prevented from occurring or substantially reduced. In addition, when hydrogen is provided in the electron transport region ETR including a metal oxide, defects in the electron transport region ETR may be effectively prevented from occurring or substantially reduced. Accordingly, in embodiments of the invention, it is possible to improve the luminous efficiency and/or luminous lifespan of the light emitting element ED by disposing or providing the hydrogen supply layer HSL in the light emitting element ED.

In addition, according to embodiments of the invention, by disposing the barrier layer BRL in a lower portion of the hydrogen supply layer HSL, it is possible to effectively prevent hydrogen impurities from diffusing in a downward direction toward the barrier layer BRL. Accordingly, it is possible to effectively prevent the hydrogen impurities from diffusing into the circuit layer DP-CL. In such embodiments, since the semiconductor pattern of the transistor TR includes an oxide semiconductor, when the hydrogen impurities are diffused into the circuit layer DP-CL, particularly into the transistor TR, properties of the transistor TR, such a threshold voltage of the transistor TR, may change. According to embodiments of the invention, by disposing or providing the barrier layer BRL in the lower portion of the hydrogen supply layer HSL, it is possible to effectively prevent the hydrogen impurities from diffusing into the transistor TR. Accordingly, it is possible to effectively prevent the generation of display defects due to the properties change of the transistor TR. That is, the display panel DP with reduced display defects may be provided.

In an embodiment, as illustrated in FIG. 7A, the first light emitting element ED-1 may include the first light emitting layer EML-R including the first quantum dot QD1, and as illustrated in FIG. 7B, the second light emitting element ED-2 may include the second light emitting layer EML-G including the second quantum dot QD2. The size (e.g., diameter) of the first quantum dot QD1 and the size (e.g., diameter) of the second quantum dot QD2 may be different from each other.

Referring to FIG. 7A and FIG. 7B, in an embodiment of resonance distances RD-1 and RD-2 of respective light emitting elements ED-1 and ED-2 may be defined as distances between an upper surface U-L1 of first layers L1-1 and L1-2 corresponding to a reflective electrode of the barrier layers BRL-1 and BRL-2 and a lower surface L-EL2 of the second electrode EL2. The upper surface U-L1 of the first layers L1-1 and L1-2 may be a surface in contact with second layers L2-1 and L2-2. The lower surface L-EL2 of the second electrode EL2 may be a surface in contact with the electron transport regions ETR-1 and ETR-2. Accordingly, the resonance distances RD-1 and RD-2 of the respective light emitting elements ED-1 and ED-2 may be defined as the sum of the thickness t2 of the second layers L2-1 and L2-2, the thickness t3 of the hydrogen supply layers HSL-1 and HSL-2, a thickness t4 of the first electrode EL1, thicknesses t5-1 and t5-2 of the hole injection regions HTR-1 and HTR-2, thicknesses of the light emitting layers EML-R and EML-G, and thicknesses of the electron injection regions ETR-1 and ETR-2.

In an embodiment, the resonance distance RD-1 of the first light emitting element ED-1 and the resonance distance RD-2 of the second light emitting element ED-2 may be different from each other. The resonance distance RD-1 of the first light emitting element ED-1 and the resonance distance RD-2 of the second light emitting element ED-2 may be set to an appropriate distance through the thicknesses t5-1 and t5-2 of the hole transport regions HTR-1 and HTR-2. The thickness t5-1 of the first hole transport region HTR-1 and the thickness t5-2 of the second hole transport region HTR-2 may be different from each other.

For example, in the hole transport regions HTR-1 and HTR-2, the hole injection layers HIL-1 and HIL-2 may be disposed on the lowermost side, and the resonance distances RD-1 and RD-2 of the respective light emitting elements ED-1 and ED-2 may be set to an appropriate distance through thicknesses T-1 and T-2 of the hole injection layers HIL-1 and HIL-2. That is, the thickness T-1 of the hole injection layer HIL-1 in the first hole transport region HTR-1 and the thickness T-2 of the hole injection layer HIL-2 in the second hole transport region HTR-2 may be different from each other.

In an embodiment, by disposing the hydrogen supply layers HSL-1 and HSL-2 between the reflective electrode (i.e., the first layer L1) and the second electrode EL2, the resonance distances RD-1 and RD-2 may be secured through the thickness t3 of the hydrogen supply layers HSL-1 and HSL-2.

In a case where a hydrogen supply layer is not disposed between a reflective electrode and a second electrode, a hole transport region is desired to be provided as thick as the thickness of the hydrogen supply layer. Since the hole transport region is typically formed by an inkjet printing process, it is desired to perform the inkjet printing process several times to form a thicker hole transport region. Since the inkjet printing process includes a process of injecting a solution, and then evaporating a solvent, a structure formed by the inkjet printing method may have a variation in thickness. Particularly, when the inkjet printing process is performed several times, the variation in thickness may be more prominent. Therefore, when a thick hole transport region is provided, the resonance distance of a light emitting element may also have a deviation, such that light emission efficiency may be reduced.

According to an embodiment, the hydrogen supply layers HSL-1 and HSL-2 may be formed by a deposition method, and thus, may be relatively easily or uniformly formed thick, and may have a relatively small deviation in thickness compared to the hole transport region HTR provided by an inkjet printing method. Accordingly, by disposing the hydrogen supply layers HSL-1 and HSL-2 formed by the deposition method between the reflective electrode (i.e., the first layer L1) and the second electrode EL2, it is possible to provide a relatively thin hole transport region HTR. Since the desired or predetermined resonance distances RD-1 and RD-2 may be more accurately provided, it is possible to improve light emission efficiency. Accordingly, the light emitting elements ED-1 and ED-2 with improved luminous efficiency and lifespan may be provided.

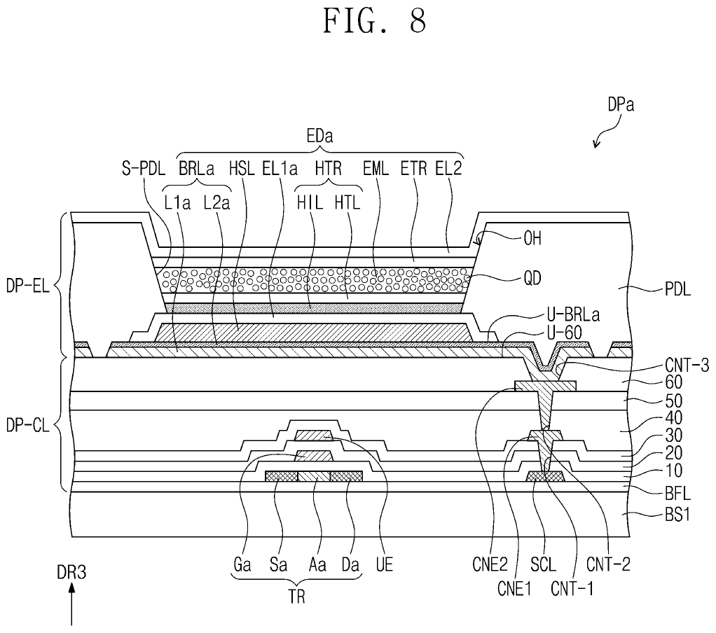

FIG. 8 is an enlarged cross-sectional view of a display panel according to an embodiment of the invention. The same/similar reference numerals are used for the same/similar components as those described with reference to FIG. 1 to FIG. 7B, and any repetitive detailed descriptions thereof will be omitted, and difference will be mainly described.

Referring to FIG. 8, in an embodiment, a light emitting element EDa of a display panel DPa may include a barrier layer BRLa, a hydrogen supply layer HSL, a first electrode EL1a, a hole transport region HTR, a light emitting layer EML, an electron transport region ETR, and a second electrode EL2.

In an embodiment, the barrier layer BRLa may be connected to a second connection electrode CNE2 via a contact-hole CNT-3 defined through a sixth insulation layer 60.

The first electrode EL1a covers the hydrogen supply layer HSL, and may be in contact with an upper surface U-BRLa of the barrier layer BRLa exposed from the hydrogen supply layer HSL. Accordingly, the first electrode EL1a may be electrically connected to the second connection electrode CNE2 via the barrier layer BRLa.

In an embodiment, the barrier layer BRLa may include a first layer L1a including a metal and a second layer L2a disposed on the first layer L1a and including a metal oxide. In such an embodiment, the upper surface U-BRLa of the barrier layer BRLa may correspond to an upper surface of the second layer L2a.

in an embodiment, as shown in FIG. 8, the first electrode EL1a may not be in contact with the sixth insulation layer 60. However, the embodiment of the invention is not limited thereto, and the first electrode EL1a may be disposed to contact not only the upper surface U-BRLa of the barrier layer BRLa but also an upper surface U-60 of the sixth insulation layer 60 as shown in FIG. 5.

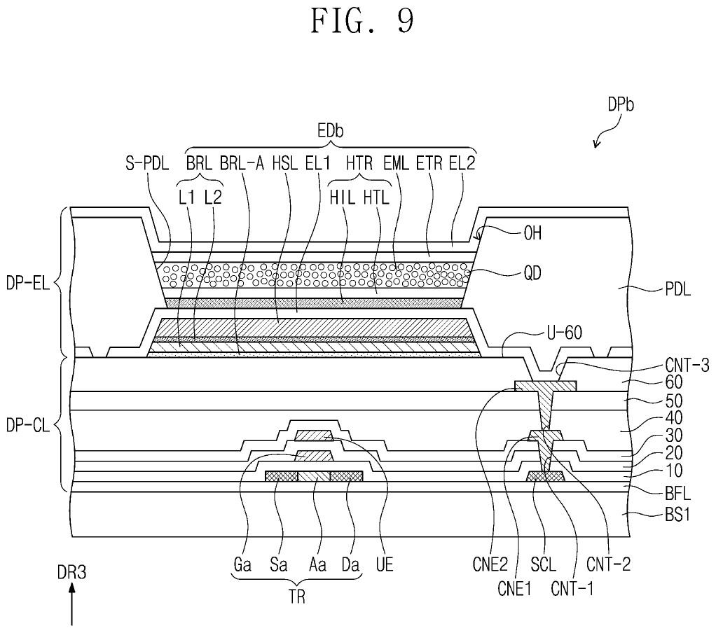

FIG. 9 is an enlarged cross-sectional view of a display panel according to an embodiment of the invention. The same/similar reference numerals are used for the same/similar components as those described with reference to FIG. 1 to FIG. 7B, and any repetitive detailed descriptions thereof will be omitted, and difference will be mainly described.

Referring to FIG. 9, in an embodiment, a light emitting element EDb of a display panel DPb may include an additional barrier layer BRL-A, a barrier layer BRL, a hydrogen supply layer HSL, a first electrode EL1, a hole transport region HTR, a light emitting layer EML, an electron transport region ETR, and a second electrode EL2.

In such an embodiment, the light emitting element EDb may further include the additional barrier layer BRL-A disposed between a circuit layer DP-CL and the barrier layer BRL. The additional barrier layer BRL-A may be disposed between a sixth insulation layer 60 and the barrier layer BRL. The additional barrier layer BRL-A may correspond to pixel regions (PXA-R, PXA-G, PXA-B, see FIG. 5) similar to the barrier layer BRL and may be provided in the form of a plurality of patterns.

The additional barrier layer BRL-A may improve adhesion between the sixth insulation layer 60 and the barrier layer BRL. In an embodiment, the additional barrier layer BRL-A may include a transparent conductive oxide (TCO).

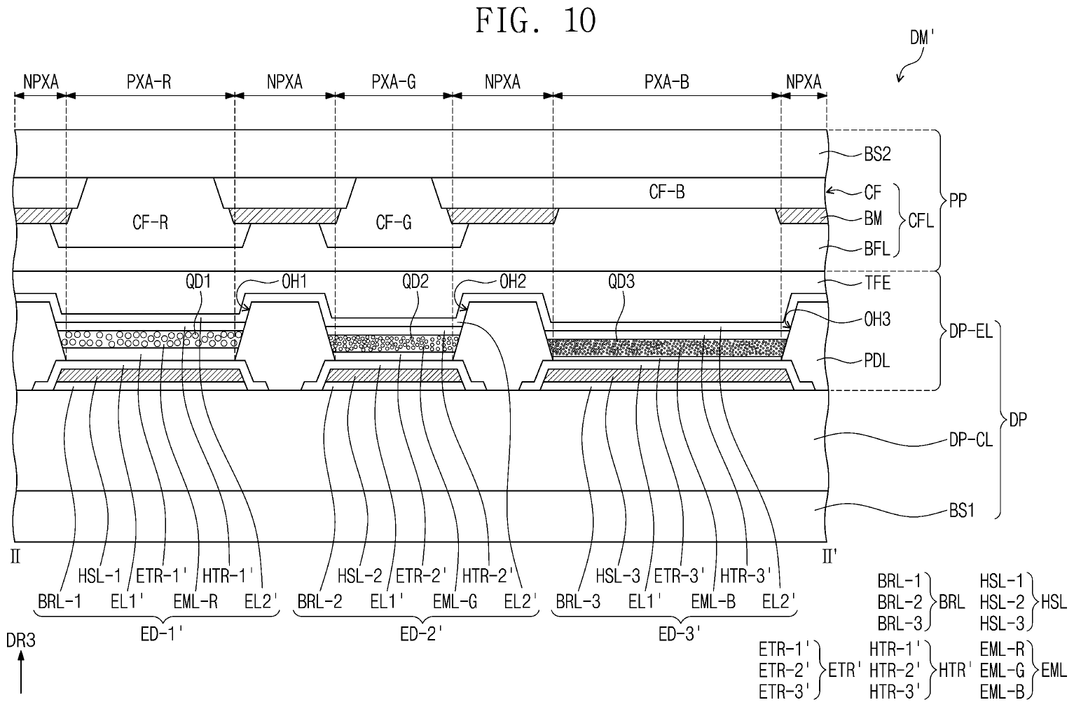

FIG. 10 is a cross-sectional view of a display module according to an embodiment of the invention taken along line II-II′ of FIG. 4. The same/similar reference numerals are used for the same/similar components as those described with reference to FIG. 1 to FIG. 7B, and any repetitive detailed descriptions thereof will be omitted, and difference will be mainly described.

Referring to FIG. 10, a display module DM′ according to an embodiment may include a display panel DP′ and an optical member PP, and the display panel DP′ may include light emitting elements ED-1′, ED-2′, and ED-3′.

Each of the light emitting elements ED-1′, ED-2′, and ED-3′ may include a barrier layer BRL, a hydrogen supply layer HSL, a first electrode EL1′, an electron transport region ETR′, a light emitting layer EML, a hole transport region HTR′, and a second electrode EL2′.

In such an embodiment, the first electrode EL1′ may be a cathode and the second electrode EL2′ may be an anode. The electron transport region ETR′ may be disposed between the first electrode EL1′ and the light emitting layer EML, and the hole transport region HTR′ may be disposed between the light emitting layer EML and the second electrode EL2′.

In a first light emitting element ED-1′, a first electron transport region ETR-1′ may be disposed between the first electrode EL1′ and a first light emitting layer EML-R, and a first hole transport region HTR-1′ may be disposed between the first light emitting layer EML-R and the second electrode EL2′. In a second light emitting element ED-2′, a second electron transport region ETR-2′ may be disposed between the first electrode EL1′ and a second light emitting layer EML-G, and a second hole transport region HTR-2′ may be disposed between the second light emitting layer EML-G and the second electrode EL2′. In a third light emitting element ED-3′, a third electron transport region ETR-3′ may be disposed between the first electrode EL1′ and a third light emitting layer EML-B, and a third hole transport region HTR-3′ may be disposed between the third light emitting layer EML-B and the second electrode EL2′.

In such an embodiment, the first to third electron transport regions ETR-1′, ETR-2′, and ETR-3′ may have different thicknesses from each other.

FIG. 10 illustrates an embodiment where the electron transport region HTR′ is provided in the form of a plurality of patterns spaced apart from each other and the first to third hole transport regions HTR-1′, HTR-2′, and HTR-3′ are respectively disposed in first to third pixel openings OH1, OH2, and OH3, but the embodiment of the invention is not limited thereto, and the hole transport region HTR′ may be provided as a common layer, and the first to third hole transport regions HTR-1′, HTR-2′, and HTR-3′ may be distinguished in or defined by portions of the common layer.

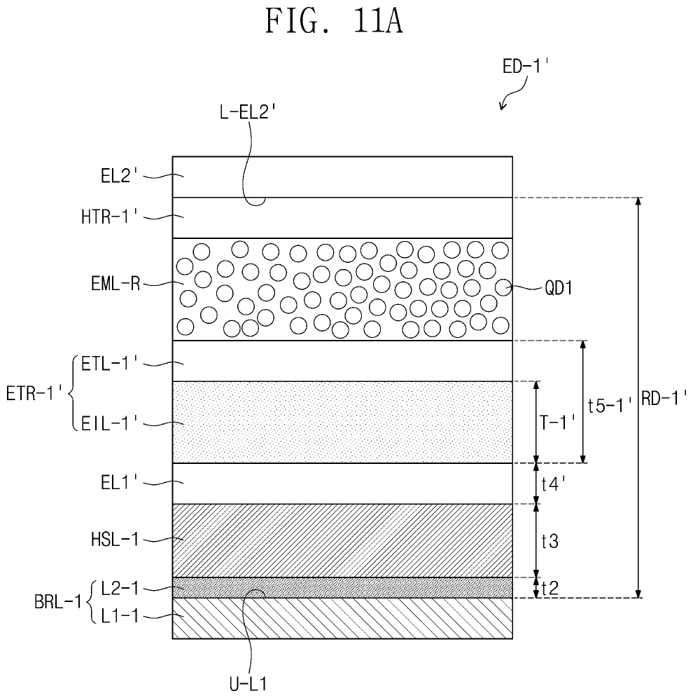

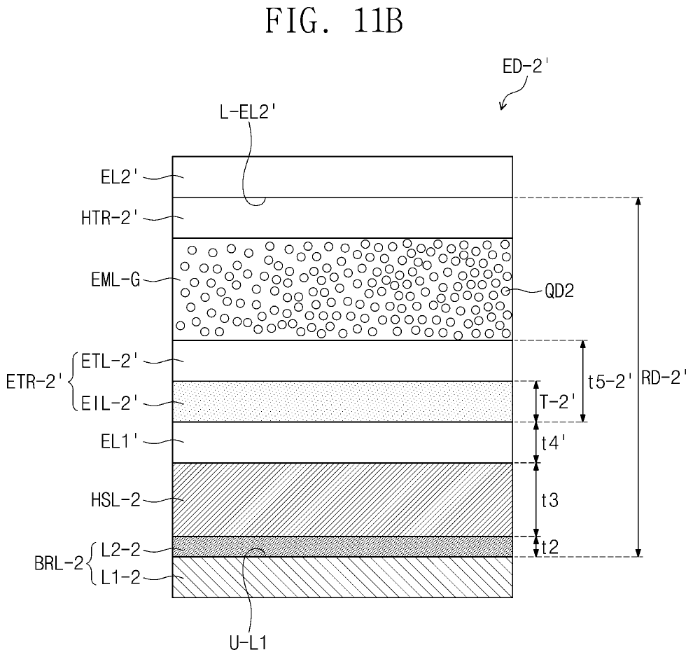

FIG. 11A and FIG. 11B are enlarged cross-sectional views of a light emitting element according to an embodiment of the invention. Among the light emitting elements ED-1′, ED-2′, and ED-3′ illustrated in FIG. 10, FIG. 11A and FIG. 11B schematically show the first light emitting element ED-1′ and the second light emitting element ED-2′, respectively. The same/similar reference numerals are used for the same/similar components as those described with reference to FIG. 1 to FIG. 7B, and any repetitive detailed descriptions thereof will be omitted, and difference will be mainly described.

Referring to FIG. 11A and FIG. 11B, the electron transport regions ETR-1′ and ETR-2′ according to the embodiment may include electron injection layers EIL-1′ and EIL-2′ and electron transport layers ETL-1′ and ETL-2′ which are sequentially stacked.

In an embodiment, the electron injection layers EIL-1′ and EIL-2′ may have higher electrical conductivity than the electron transport layers ETL-1′ and ETL-2′. Materials included in the electron injection layers EIL-1′ and EIL-2′ may have higher electrical conductivity than materials included in the electron transport layers ETL-1′ and ETL-2′. In an embodiment, for example, the electron injection layers EIL-1′ and EIL-2′ may include ZnO, and the electron transport layers ETL-1′ and ETL-2′ may include ZnMgO. However, this is merely an example, and the embodiment of the invention is not limited thereto.

Resonance distances RD-1′ and RD-2′ of the respective light emitting elements ED-1′ and ED-2′ may be defined as distances between an upper surface U-L1 of first layers L1-1 and L1-2 corresponding to a reflective electrode of barrier layers BRL-1 and BRL-2 and a lower surface L-EL2′ of a second electrode EL2′. The upper surface U-L1 of the first layers L1-1 and L1-2 may be a surface in contact with second layers L2-1 and L2-2. The lower surface L-EL2′ of the second electrode EL2′ may be a surface in contact with hole injection regions HTR-1′ and HTR-2′. Accordingly, the resonance distances RD-1′ and RD-2′ of the respective light emitting elements ED-1′ and ED-2′ may be defined as the sum of a thickness t2 of the second layers L2-1 and L2-2, a thickness t3 of hydrogen supply layers HSL-1 and HSL-2, a thickness t4′ of a first electrode EL1′, thicknesses t5-1′ and t5-2′ of the electron injection regions ETR-1′ and ETR-2′, thicknesses of light emitting layers EML-R and EML-G, and thicknesses of the hole injection regions HTR-1′ and HTR-2′.

The resonance distance RD-1′ of the first light emitting element ED-1′ and the resonance distance RD-2′ of the second light emitting element ED-2′ may be different from each other. In an embodiment, the resonance distance RD-1′ of the first light emitting element ED-1′ and the resonance distance RD-2′ of the second light emitting element ED-2′ may be set to an appropriate distance through the thicknesses t5-1′ and t5-2′ of the electron transport regions ETR-1′ and ETR-2′. The thickness t5-1′ of the first electron transport region ETR-1′ and the thickness t5-2′ of the second electron transport region ETR-2′ may be different from each other.

For example, in the electron transport regions ETR-1′ and ETR-2′, the electron injection layers EIL-1′ and EIL-2′ may be disposed on the lowermost side, and the resonance distances RD-1′ and RD-2′ of the respective light emitting elements ED-1′ and ED-2′ may be set to an appropriate distance through thicknesses T-1′ and T-2′ of the electron injection layers EIL-1′ and EIL-2′. That is, the thickness T-1′ of the electron injection layer EIL-1′ in the first electron transport region ETR-1′ and the thickness T-2′ of the electron injection layer EIL-2′ in the second electron transport region ETR-2′ may be different from each other.

In such an embodiment, by disposing the hydrogen supply layers HSL-1 and HSL-2 between a reflective electrode (i.e., a first layer L1) and the second electrode EL2′, the resonance distances RD-1′ and RD-2′ may be secured through the thickness t3 of the hydrogen supply layers HSL-1 and HSL-2.

In a case, where a hydrogen supply layer is not disposed between a reflective electrode and a second electrode, an electron transport region is desired to be provided as thick as the thickness of the hydrogen supply layer. Since the electron transport region is typically formed by an inkjet printing process, when a thick electron transport region is provided, a variation in thickness may become prominent. Accordingly, the resonance distance of a light emitting element may also have a deviation, so that light emission efficiency may not be improved.

According to an embodiment, by disposing the hydrogen supply layers HSL-1 and HSL-2 formed by a deposition method between the reflective electrode (i.e., the first layer L1) and the second electrode EL2′, it is possible to provide a relatively thin electron transport region ETR′, so that it is possible to provide the required resonance distances RD-1′ and RD-2′ more accurately. Accordingly, the light emitting elements ED-1′ and ED-2′ with improved luminous efficiency and lifespan may be provided.

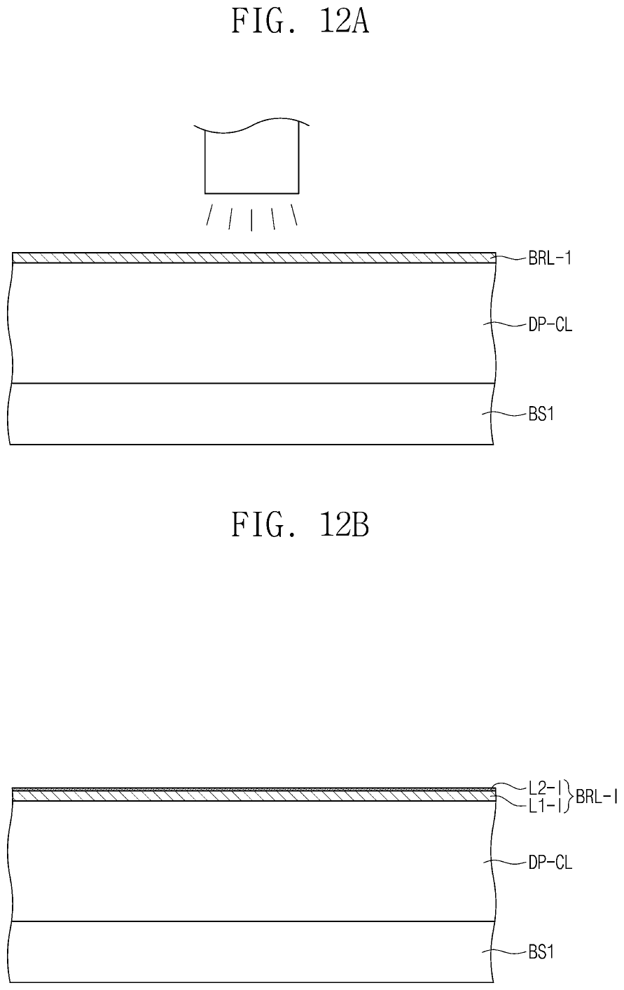

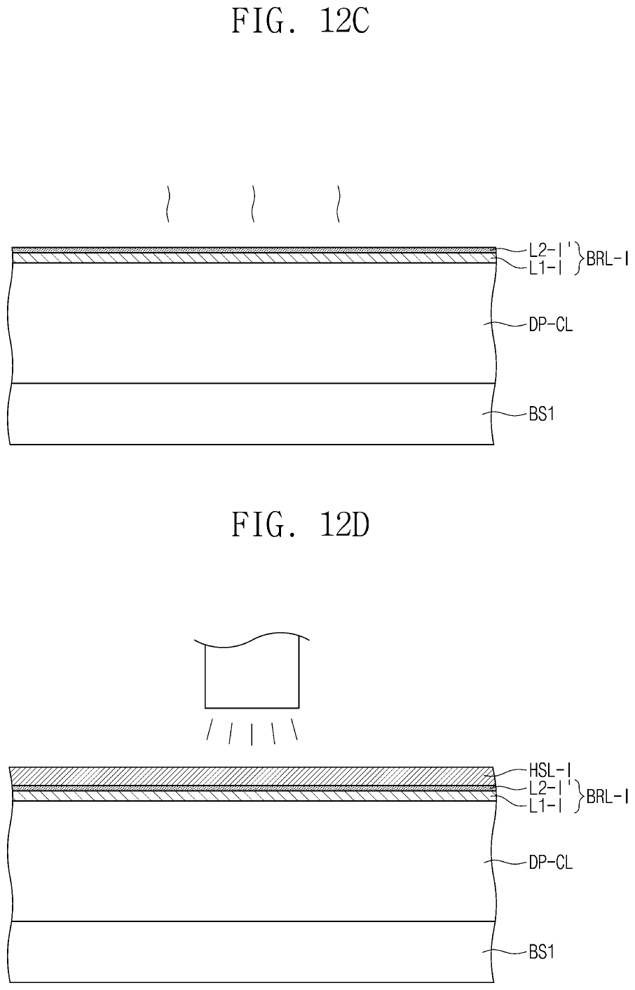

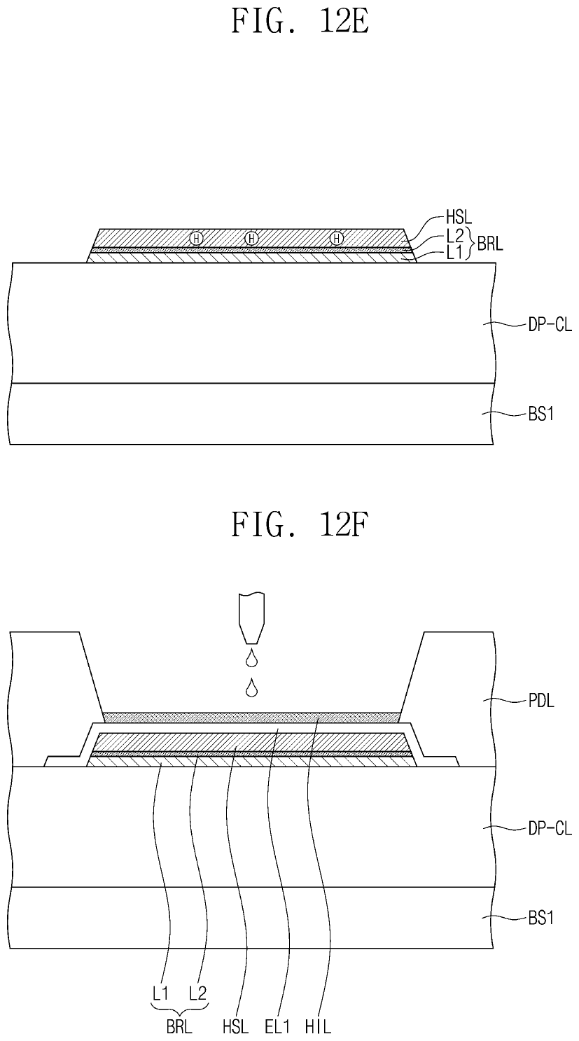

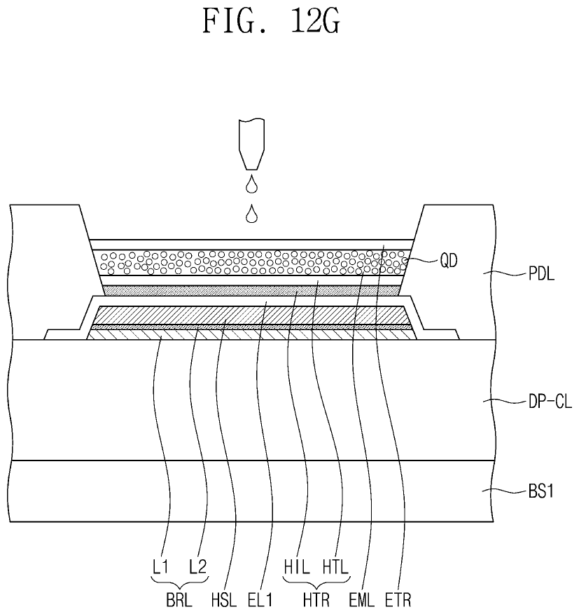

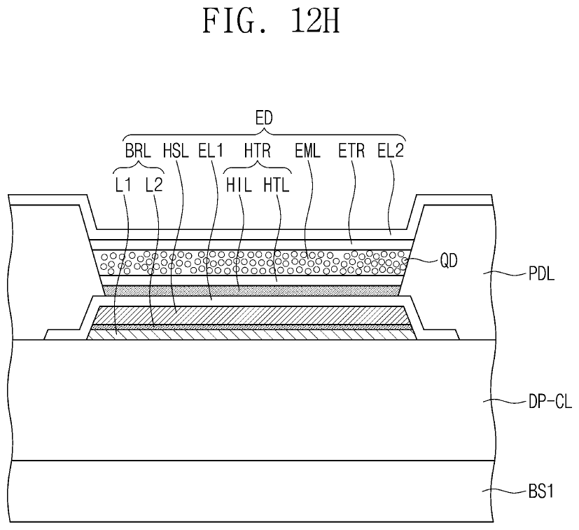

FIG. 12A to FIG. 12H are cross-sectional views schematically showing processes of a method for manufacturing a light emitting element according to an embodiment of the invention. Hereinafter, with reference to FIG. 12A to FIG. 12H, an embodiment of a method for manufacturing the light emitting element ED will be described in detail.

As illustrated in FIG. 12A and FIG. 12B, the method for manufacturing the light emitting element ED (see FIG. 12H) according to an embodiment may include forming a preliminary barrier layer BRL-I. The forming of the preliminary barrier layer BRL-I may include depositing a metal on a circuit layer DP-CL.

In an embodiment, as illustrated in FIG. 12B, the preliminary barrier layer BRL-I may include a first preliminary layer L1-I including a metal and a second preliminary layer L2-I including a metal oxide. In an embodiment, the second preliminary layer L2-I may include the metal oxide included in the first preliminary layer L1-I. In an embodiment, for example, the first preliminary layer L1-I may include aluminum (Al), and the second preliminary layer L2-I may be a layer formed by oxidation of an interface of the first preliminary layer L1-I and may include an aluminum oxide (Al_{X}O_{y}).

According to another embodiment of the invention, in the forming of the preliminary barrier layer BRL-I, the first preliminary layer L1-I and the second preliminary layer L2-I may be formed by a separate deposition process, and in such an embodiment, the first preliminary layer L1-I may include a first metal and the second preliminary layer L2-I may include an oxide of a second metal which is different from the first metal.

As illustrated in FIG. 12C, the forming of the preliminary barrier layer BRL-I according to an embodiment may further include increasing the thickness of a second preliminary layer L2-I′. After the depositing of the metal, a separate heat treatment process or plasma treatment process may be performed. For example, the plasma treatment process may be a surface treatment process using O₂ plasma.

The second preliminary layer L2-I′ after the heat treatment process or plasma treatment process may become thicker than the second preliminary layer L2-I (see FIG. 12B) before the heat treatment process or plasma treatment process. As a result, a second layer L2 formed from the second preliminary layer L2-I′ may more reliably or effectively block the diffusion of hydrogen impurities into a lower side of the second layer L2.

As illustrated in FIG. 12D, the method for manufacturing the light emitting element ED (see FIG. 12H) according to an embodiment may include forming a preliminary hydrogen supply layer HSL-I. The forming of the preliminary hydrogen supply layer HSL-I may include depositing an inorganic material on the preliminary barrier layer BRL-I.

In the forming of the preliminary hydrogen supply layer HSL-I, the depositing of the inorganic material may be performed by a chemical vapor deposition (CVD) method. According to an embodiment, a raw material gas injected during the chemical vapor deposition may include hydrogen. In an embodiment, for example, a preliminary hydrogen supply layer may be formed by injecting SiH₄ gas and NH₄ gas, thereby depositing an inorganic film of SiNₓ by a chemical vapor deposition method. However, the embodiment of the invention is not limited thereto. In an embodiment, for example, SiH₄ gas and N₂O gas may be injected to deposit an inorganic film of SiOₓ by chemical vapor deposition, or SiH₄ gas, N₂O gas, and N₂ gas may be injected to deposit an inorganic film of SiOₓN_{y} by chemical vapor deposition, thereby forming a preliminary hydrogen supply layer. The depositing of the inorganic material may be performed by a plasma-enhanced chemical vapor deposition (PECVD) method among chemical vapor deposition methods.

As illustrated in FIG. 12D and FIG. 12E, the method for manufacturing the light emitting element ED (see FIG. 12H) according to an embodiment may include forming a barrier layer BRL and a hydrogen supply layer HSL. in an embodiment, the barrier layer BRL may be formed from the preliminary barrier layer BRL-I, e.g., by patterning the preliminary barrier layer BRL-IIn such an embodiment, the hydrogen supply layer HSL may be formed from the preliminary hydrogen supply layer HSL-I, e.g., by patterning the preliminary hydrogen supply layer HSL-I.

In an embodiment, the patterning process of the preliminary barrier layer BRL-I and the patterning process of the preliminary hydrogen supply layer HSL-I may be performed by a photolithography process. However, the patterning process of the preliminary barrier layer BRL-I and the patterning process of the preliminary hydrogen supply layer HSL-I are not limited to any one embodiment.

The patterning process of the preliminary barrier layer BRL-I and the patterning process of the preliminary hydrogen supply layer HSL-I may be simultaneously performed, or separately performed.

Alternatively, after the forming of the preliminary barrier layer BRL-I and before the forming of the preliminary hydrogen supply layer HSL-I, the preliminary barrier layer BRL-I may be patterned to form the barrier layer BRL from the preliminary barrier layer BRL-I. In this process, the preliminary hydrogen supply layer HSL-I may be formed on the patterned barrier layer BRL.

As illustrated in FIG. 12E, since a gas including hydrogen is injected in the process of forming the preliminary hydrogen supply layer HSL-I, the hydrogen remains in the final formed hydrogen supply layer HSL, so that hydrogen impurities may be included in the hydrogen supply layer HSL.

Thereafter, as illustrated in FIG. 12F, the method for manufacturing the light emitting element ED (see FIG. 12H) according to an embodiment may include forming a first electrode EL1.

The forming of the first electrode EL1 may be performed by depositing a transparent conductive material on the circuit layer DP-CL. The first electrode EL1 may be formed to cover the hydrogen supply layer HSL and the barrier layer BRL. However, the embodiment of the invention is not limited thereto, and depending on an embodiment, the first electrode EL1 may be formed to cover the hydrogen supply layer HSL and be in contact with an upper surface of the barrier layer BRL exposed from the hydrogen supply layer HSL.

A pixel definition layer PDL may be formed after the forming of the first electrode EL1. The pixel definition layer PDL may be disposed on the circuit layer DP-CL and be formed to expose a portion of the first electrode EL1. In such an embodiment, a pixel opening OH exposing a portion of the first electrode EL1 may be formed through or by the pixel definition layer PDL.

Thereafter, as illustrated in FIG. 12F and FIG. 12G, the method for manufacturing the light emitting element ED (see FIG. 12H) according to an embodiment may include forming a functional layer. In the specification, the functional layer may correspond to a hole transport region HTR or an electron transport region ETR. The forming of the functional layer may be performed by an inkjet printing method.

The method for manufacturing the light emitting element ED (see FIG. 12H) according to an embodiment may include forming the hole transport region HTR on the first electrode EL1, and the forming of the hole transport region HTR may include forming a hole injection layer HIL and forming a hole transport layer HTL. The forming of the hole injection layer HIL and the forming of the hole transport layer HTL may both be performed by an inkjet printing method. FIG. 12F schematically illustrates the process of forming the hole injection layer HIL.

In an embodiment, the hole injection layer HIL may be formed in an appropriate thickness for each light emitting element ED (see FIG. 12H) to provide a resonance distance desired for each light emitting element ED (see FIG. 12H). According to an embodiment, by providing the hydrogen supply layer HSL between a first layer L1 corresponding to a reflective electrode and a second electrode EL2 (see FIG. 12H) in the light emitting element ED (see FIG. 12H), the hole injection layer HIL may be provided as thin as the hydrogen supply layer HSL. According to an embodiment, the hole injection layer HIL may be formed by a single inkjet printing process. Compared to a case in which the hole injection layer HIL is formed thick by performing an inkjet printing process several times, a deviation in thickness deviation may be reduced. Accordingly, in embodiments of the invention, since it is possible to more accurately provide a desired or predetermined resonance distance, such that light emission efficiency is improved.

FIG. 12F and FIG. 12G illustrate an embodiment of the forming of the hole transport region HTR including the hole injection layer HIL and the hole transport layer HTL, but the embodiment of the invention is not limited thereto, and the forming of the hole transport region HTR may further include forming a hole buffer layer and/or forming an electron blocking layer.

Thereafter, as illustrated in FIG. 12G, the method for manufacturing the light emitting element ED (see FIG. 12H) according to an embodiment may include forming a light emitting layer EML and forming an electron transport region ETR. The forming of the light emitting layer EML and the forming of the electron transport region ETR may both be performed by an inkjet printing process.

FIG. 12G illustrates an embodiment of the forming of a single-layered electron transport region ETR, but the forming of the electron transport region ETR may include at least one selected from forming a hole blocking layer, forming an electron transport layer, and forming an electron injection layer.

FIG. 12F and FIG. 12G illustrate an embodiment of the forming of the hole transport region HTR between the first electrode EL1 and the light emitting layer EML and the forming of the electron transport region ETR on the light emitting layer EML, but the embodiment of the invention is not limited thereto, and as illustrated in FIG. 10, the electron transport region ETR′ may be formed between the first electrode EL1′ and the light emitting layer EML and the hole transport region HTR′ may be formed on the light emitting layer EML. In this case, the resonance distance of the light emitting element ED′ (see FIG. 10) may be controlled by the thickness of the electron transport region ETR′ (see FIG. 10). For example, the resonance distance of the light emitting element ED′ (see FIG. 10) may be controlled by the thicknesses of the electron injection layer EIL-1′ and EIL-2′ (see FIG. 11A and FIG. 11B) in the electron transport region ETR′ (see FIG. 10).

Thereafter, as illustrated in FIG. 12H, the method for manufacturing the light emitting element ED according to an embodiment may include forming a second electrode EL2. The forming of the second electrode EL2 may be performed by a deposition method. As a result, the light emitting element ED including the barrier layer BRL, the hydrogen supply layer HSL, the first electrode EL1, the hole transport region HTR, the light emitting layer EML, the electron transport region ETR, and the second electrode EL2 may be formed.

According to embodiments of the invention, a light emitting element includes a hydrogen supply layer, such that it is possible to provide a light emitting element having improved luminous efficiency and lifespan, a display panel including the light emitting element, and a method for manufacturing the light emitting element. In addition, according to embodiments of the invention, by providing a hydrogen supply layer on a reflective electrode, it is possible to provide a light emitting element having improved process reliability, a display panel including the light emitting element, and a method for manufacturing the light emitting element. In addition, according to embodiments of the invention, by allowing a light emitting element to include a barrier layer disposed on a lower side of a hydrogen supply layer, variation in properties of a transistor in a pixel driving circuit may be substantially reduced or effectively prevented, and accordingly, it is possible to provide a display panel with reduced display defects.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a base layer;
a circuit layer disposed on the base layer; and
a light emitting element disposed on the circuit layer, wherein the light emitting element includes:
a barrier layer including a metal and a metal oxide;
a hydrogen supply layer disposed on the barrier layer, and including an inorganic material;
a first electrode disposed on the hydrogen supply layer;
a light emitting layer disposed on the first electrode, and including a quantum dot; and
a second electrode disposed on the light emitting layer.

2. The display panel of claim 1, wherein the hydrogen supply layer comprises hydrogen impurities, wherein the hydrogen impurities are diffused into the light emitting layer.

3. The display panel of claim 1, wherein the hydrogen supply layer comprises at least one selected from silicon nitride, silicon oxide, and silicon oxynitride.

4. The display panel of claim 1, wherein a thickness of the hydrogen supply layer is about 2000 angstroms or less.

5. The display panel of claim 1, wherein the barrier layer comprises:
a first layer including a metal; and
a second layer disposed on the first layer, and including a metal oxide.

6. The display panel of claim 5, wherein a resonance distance of the light emitting element is defined as a distance between an upper surface of the first layer and a lower surface of the second electrode.

7. The display panel of claim 5, wherein:
a thickness of the first layer is about 500 angstroms or less; and
a thickness of the second layer is in a range of about 50 angstroms to about 100 angstroms.

8. The display panel of claim 1, wherein a content of the metal oxide in the barrier layer gradually increases as being upward in a direction toward the light emitting layer.

9. The display panel of claim 1, wherein the metal oxide comprises aluminum oxide.

10. The display panel of claim 1, wherein the metal comprises at least one selected from aluminum and silver.

11. The display panel of claim 1, wherein the circuit layer comprises:
at least one transistor electrically connected to the light emitting element;
a connection electrode electrically connected to the transistor; and
an insulation layer disposed between the connection electrode and the barrier layer, wherein the transistor includes an oxide semiconductor.

12. The display panel of claim 11, wherein the first electrode covers the hydrogen supply layer and the barrier layer, and is connected to the connection electrode via a contact-hole defined through the insulation layer.

13. The display panel of claim 11, wherein:
the barrier layer is connected to the connection electrode via a contact-hole defined through the insulation layer; and
the first electrode covers the hydrogen supply layer, and is in contact with an upper surface of the barrier layer exposed from the hydrogen supply layer.

14. The display panel of claim 11, further comprising
an additional barrier layer disposed between the insulation layer and the barrier layer and in contact with each of the insulation layer and the barrier layer, wherein the additional barrier layer includes a transparent conductive oxide.

15. The display panel of claim 1, wherein the first electrode comprises a transparent conductive oxide.

16. The display panel of claim 1, wherein a thickness of the first electrode is in a range of about 500 angstroms to about 1000 angstroms.

17. The display panel of claim 1, wherein the light emitting element is provided in plural, and a plurality of light emitting elements includes a first light emitting element and a second light emitting element, which emit light of different colors, respectively, wherein
the barrier layer of the first light emitting element and the barrier layer of the second light emitting element are spaced apart from each other, and
the hydrogen supply layer of the first light emitting element and the hydrogen supply layer of the second light emitting element are spaced apart from each other.

18. The display panel of claim 17, wherein:
the light emitting layer of the first light emitting element comprises a first quantum dot;
the light emitting layer of the second light emitting element comprises a second quantum dot; and
a diameter of the first quantum dot and a diameter of the second quantum dot are different from each other.

19. The display panel of claim 1, wherein the light emitting element further comprises:
a hole transport region disposed between the first electrode the light emitting layer; and
an electron transport region disposed between the light emitting layer and the second electrode.

20. The display panel of claim 19, wherein the hydrogen supply layer comprises hydrogen impurities, wherein the hydrogen impurities are diffused into the electron transport region.

21. The display panel of claim 19, wherein the light emitting element is provided in plural, and a plurality of light emitting elements includes a first light emitting element and a second light emitting element, which emit light of different colors, respectively,
wherein a thickness of the hole transport region of the first light emitting element and a thickness of the hole transport region of the second light emitting element are different from each other.

22. The display panel of claim 21, wherein:
the hole transport region of each of the first light emitting element and the second light emitting element comprises a hole injection layer and a hole transport layer which are sequentially stacked one on another; and
a thickness of the hole injection layer of the first light emitting element and a thickness of the hole injection layer of the second light emitting element are different from each other.

23. The display panel of claim 1, wherein the light emitting element further comprises:
an electron transport region disposed between the first electrode the light emitting layer; and
a hole transport region disposed between the light emitting layer and the second electrode.

24. The display panel of claim 23, wherein the light emitting element is provided in plural, and a plurality of light emitting elements includes a first light emitting element and a second light emitting element, which emit light of different colors, respectively,
wherein a thickness of the electron transport region of the first light emitting element and a thickness of the electron transport region of the second light emitting element are different from each other.

25. A method for manufacturing a light emitting element, the method comprising:
forming a barrier layer including a metal and a metal oxide;
forming a hydrogen supply layer disposed on the barrier layer and including an inorganic material;
forming a first electrode on the hydrogen supply layer;
forming a light emitting layer including a quantum dot on the first electrode; and
forming a second electrode on the light emitting layer.

26. The method of claim 25, wherein the forming the hydrogen supply layer comprises depositing the inorganic material, and
wherein the depositing the inorganic material is performed by a chemical vapor deposition method by injecting a gas including hydrogen.

27. The method of claim 25, wherein the forming the barrier layer comprises:
forming a preliminary barrier layer including a first preliminary layer including the metal and a second preliminary layer disposed on the first preliminary layer and including the metal oxide; and
increasing a thickness of the second preliminary layer, wherein the increasing the thickness of the second preliminary layer is performed by a heat treatment process or a plasma treatment process.

28. The method of claim 25, further comprising,
after the forming the first electrode and before the forming the light emitting layer, forming a functional layer on the first electrode,
wherein the forming the functional layer is performed by an inkjet printing process.
